(19) United States
(12) Patent Application Publication
(10) Pub. No.: US 2025/0258571 A1
(43) Pub. Date: Aug. 14, 2025

(54) TOUCH SENSING UNIT AND DISPLAY APPARATUS INCLUDING THE SAME

(71) Applicant: Samsung Display Co., Ltd., Yongin-Si (KR)

(72) Inventors: Taeyong Eom, Yongin-si (KR); Wonil Lee, Yongin-si (KR); Youngbae Jung, Yongin-si (KR)

(21) Appl. No.: 18/935,648

(22) Filed: Nov. 3, 2024

(30) Foreign Application Priority Data
Feb. 8, 2024 (KR) 10-2024-0019861

(51) Int. Cl. G06F 3/044

(52) U.S. Cl. CPC G06F 3/0446; G06F 3/0443

(57) ABSTRACT

A touch sensing unit includes touch sensors arranged in first to n^{th} rows and first to m^{th} columns, wherein each of the touch sensors includes a touch electrode, wherein a number of the touch sensors located in an a^{th} column is greater than a number of the touch sensors located in a b^{th} column (a and b are different natural numbers equal to or less than m), and wherein an area of the touch electrode of a first touch sensor located in the a^{th} column is less than an area of the touch electrode of a second touch sensor located in the b^{th} column.

### CROSS-REFERENCE TO RELATED APPLICATION

This application is based on and claims priority under 35 U.S.C. § 119 to Korean Patent Application No. 10-2024-0019861, filed on Feb. 8, 2024, in the Korean Intellectual Property Office, the disclosure of which is incorporated by reference herein in its entirety.

### BACKGROUND

### 1. Field

The present disclosure relates to a touch sensing unit and a display apparatus including the same.

### 2. Description of the Related Art

A display area of a display apparatus may have an irregular shape, or a regular shape such as a quadrangular shape or a circular shape. That is, a display apparatus may display an image through a display area having any of various shapes and areas, and may detect whether a touch has occurred thereon by using a touch sensing unit included in the display apparatus.

When a display apparatus has a planar shape, lengths of touch electrode lines including a plurality of touch electrodes may be varied according to positions. For example, when a display apparatus has a display area having an irregular shape, rather than a circular or quadrangular shape, lengths of sensing electrode lines or driving electrode lines included in a touch sensing unit may be different from each other according to the positions where the sensing electrode lines, or the driving electrode lines are.

### SUMMARY

The present disclosure may include a touch sensing unit which has an increasing accuracy of touch sensing by reducing the difference in area of touch electrodes included in touch electrode lines having different lengths and a display apparatus including the touch sensing unit. However, the embodiments set forth below are examples and do not limit the scope of the present disclosure.

Additional aspects will be set forth in the description which follows and will be apparent from the description.

According to an embodiment, a touch sensing unit includes touch sensors arranged in first to n^{th} rows and first to m^{th} columns, wherein each of the touch sensors includes a touch electrode, wherein a number of the touch sensors located in an a^{th} column is greater than a number of the touch sensors located in a b^{th} column (a and b are different natural numbers equal to or less than m), and wherein an area of the touch electrode of a first touch sensor located in the a^{th} column is less than an area of the touch electrode of a second touch sensor located in the b^{th} column.

The touch electrode may include a driving electrode and a sensing electrode, and an area of the driving electrode of the first touch sensor may be less than an area of the driving electrode of the second touch sensor.

An area of the sensing electrode of the first touch sensor may be less than an area of the sensing electrode of the second touch sensor.

In a plan view, an interval between the driving electrode and the sensing electrode of the first touch sensor may be greater than an interval between the driving electrode and the sensing electrode of the second touch sensor.

The first touch sensor may further include a first dummy pattern located inside each of the driving electrode and the sensing electrode of the first touch sensor.

The second touch sensor may further include a second dummy pattern located inside each of the driving electrode and the sensing electrode of the second touch sensor, and an area of the first dummy pattern of the first touch sensor may be greater than an area of the second dummy pattern of the second touch sensor.

In a plan view, an interval between the driving electrode and the sensing electrode of the first touch sensor may be same as an interval between the driving electrode and the sensing electrode of the second touch sensor.

In a plan view, an interval between the driving electrode and the sensing electrode of the first touch sensor may be less than an interval between the driving electrode and the sensing electrode of the second touch sensor.

Each of the driving electrode and the sensing electrode of the first touch sensor may have a ring shape, and each of the driving electrode and the sensing electrode of the second touch sensor may have a non-ring shape.

A number of the touch sensors located in a c^{th} column may be less than a number of the touch sensors located in the b^{th} column (c is a natural number different from a and b and equal to or less than m), and an area of the touch electrode of the second touch sensor located in the b^{th} column may be less than an area of the touch electrode of a third touch sensor located in the c^{th} column.

An area of the touch electrode of a fourth touch sensor located in the a^{th} column and located in a different row than the first touch sensor may be same as an area of the touch electrode of the first touch sensor.

The first touch sensor and the second touch sensor may be located in a same row, and an area of the touch electrode of a fourth touch sensor located in the a^{th} column and located in a different row than the first touch sensor may be different from an area of the touch electrode of the first touch sensor.

A number of the touch sensors located in a p^{th} row may be greater than a number of the touch sensors located in a q^{th} row (p and q are different natural numbers equal to or less than n), wherein the first touch sensor may be located in the p^{th} row, and the fourth touch sensor may be located in the q^{th} row, and wherein an area of the touch electrode of the first touch sensor may be less than an area of the touch electrode of the fourth touch sensor.

According to an embodiment, a display apparatus includes a substrate, a display layer disposed on the substrate and including a light-emitting element, and a touch sensing unit disposed on the display layer and including touch sensors arranged in first to n^{th} rows and first to m^{th} columns, and each of the touch sensors includes a touch electrode (each of n and m is a natural number each equal to or greater than 3), wherein a number of the touch sensors located in an a^{th} column is greater than a number of the touch sensors located in a b^{th} column (a and b are different natural numbers equal to or less than m), and wherein an area of the touch electrode of a first touch sensor located in the a^{th} column is less than an area of the touch electrode of a second touch sensor located in the b^{th} column.

The touch electrode may include a driving electrode and a sensing electrode, and an area of the driving electrode of the first touch sensor may be less than an area of the driving electrode of the second touch sensor.

In a plan view, an interval between the driving electrode and the sensing electrode of the first touch sensor may be greater than an interval between the driving electrode and the sensing electrode of the second touch sensor.

The first touch sensor may further include a first dummy pattern located inside each of the driving electrode and the sensing electrode of the first touch sensor.

The second touch sensor may further include a second dummy pattern located inside each of the driving electrode and the sensing electrode of the second touch sensor, and an area of the first dummy pattern of the first touch sensor may be greater than an area of the second dummy pattern of the second touch sensor.

In a plan view, an interval between the driving electrode and the sensing electrode of the first touch sensor may be less than an interval between the driving electrode and the sensing electrode of the second touch sensor.

The first touch sensor and the second touch sensor may be located in a same row, and an area of the touch electrode of a fourth touch sensor located in the a^{th} column and located in a different row than the first touch sensor may be different from an area of the touch electrode of the first touch sensor.

### BRIEF DESCRIPTION OF THE DRAWINGS

The above and other aspects, features, and advantages of the present disclosure will become more apparent by reference to the following description taken in conjunction with the accompanying drawings.

FIG. 1 is a plan view schematically illustrating a display apparatus, according to an embodiment.

FIG. 2 is a cross-sectional view schematically illustrating the display apparatus of FIG. 1.

FIG. 3 is a plan view schematically illustrating a touch sensing unit included in the display apparatus.

FIG. 4 is an enlarged view schematically illustrating a portion ‘E’ of FIG. 3.

FIGS. 5 and 6 are enlarged views schematically illustrating touch sensors located at different positions illustrated in FIG. 3.

FIG. 7 is an enlarged view schematically illustrating the portion ‘E’ of FIG. 3, according to an embodiment.

FIGS. 8 and 9 are enlarged views schematically illustrating touch sensor located at different positions illustrated in FIG. 3.

FIGS. 10 and 11 are enlarged views schematically illustrating touch sensors located at different positions illustrated in FIG. 3, according to an embodiment.

FIGS. 12 and 13 are enlarged views schematically illustrating touch sensors located at different positions illustrated in FIG. 3, according to an embodiment.

FIG. 14 is an enlarged view schematically illustrating touch sensors located at different positions illustrated in FIG. 3, according to an embodiment.

FIG. 15 is a plan view schematically illustrating a touch sensing unit included in the display apparatus.

FIG. 16 is an enlarged view schematically illustrating touch sensors located at different positions illustrated in FIG. 15.

FIG. 17 is an enlarged view schematically illustrating touch sensors located at different positions illustrated in FIG. 15, according to an embodiment.

FIG. 18 is an enlarged view schematically illustrating touch sensors located at different positions illustrated in FIG. 15, according to an embodiment.

FIG. 19 is a cross-sectional view schematically illustrating the display apparatus.

### DETAILED DESCRIPTION

Hereinafter, specific embodiments of the present disclosure are explained in detail with reference to the accompanying drawings. Like numerals refer to like elements throughout. In this regard, embodiments of the present disclosure may have different forms and should not be construed as being limited to the descriptions set forth herein. Accordingly, the embodiments are merely described below, by referring to the drawings, to explain aspects of the present disclosure. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As the present disclosure allows for various changes and can have numerous embodiments, specific embodiments will be illustrated in the drawings and described in the detailed description. The effects and features of the present disclosure, as well as the methods for achieving them will become clear with reference to the detailed embodiments described below provided with the drawings. However, it should be noted that the present disclosure is not limited to the following embodiments and may be implemented in various forms.

Hereinafter, embodiments will be described in detail with reference to the accompanying drawings, wherein the same or corresponding elements are denoted by the same reference numerals throughout and a repeated description thereof is omitted.

While such terms as “first,” “second,” etc., may be used to describe various components, such components are not be limited to the above terms. The above terms are used only to distinguish one component from another.

In the following embodiments, an expression used in the singular encompasses the expression of the plural, unless it has a clearly different meaning in the context.

It will be understood that the terms “including,” “having,” and “comprising” are intended to indicate the existence of the features or elements described in the specification, and are not intended to preclude the possibility that one or more other features or elements may exist or may be added.

It will be understood that when a layer, an area, or an element is referred to as being “on” another layer, area, or element, it may be directly on the other layer, area, or element, or intervening layers, areas, or elements may be present therebetween.

Sizes of components in the drawings may be exaggerated or reduced for convenience of explanation. For example, because sizes and thicknesses of components in the drawings are arbitrarily illustrated for convenience of explanation, the present disclosure is not limited thereto.

The order of the process or method understood in the description of the processing process, manufacturing method, etc. may be different from the described order. For example, two consecutively described processes may be performed at the same time or substantially at the same time or may be performed in an order opposite to the described order.

It will be understood that when a layer, a region, or a component is referred to as being “connected” to another layer, region, or component, it may be “directly connected” to the other layer, region, or component or may be “indirectly connected” to another layer, region, or component with other layers, regions, or components interposed therebetween. It will be understood that when an element is referred to as being “electrically connected” with other elements, it may be directly and electrically connected to other elements, or may be indirectly and electrically connected to other element through an intermediate element.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

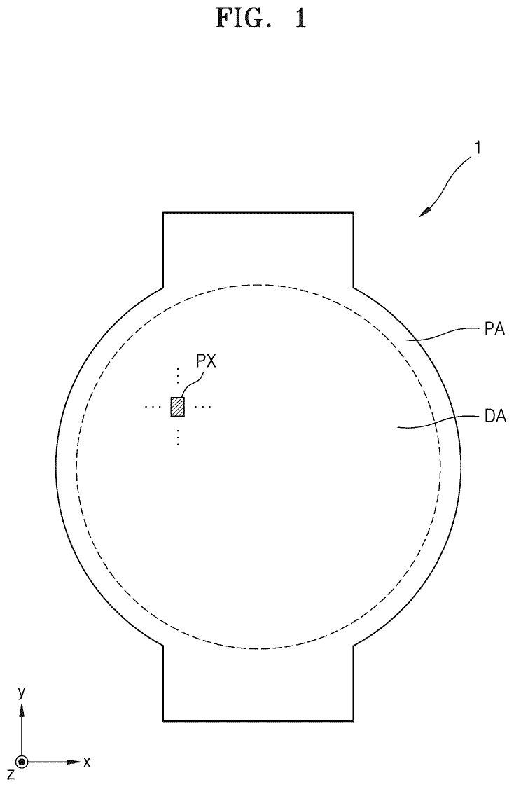

FIG. 1 is a plan view schematically illustrating a display apparatus 1, according to an embodiment.

Referring to FIG. 1, the display apparatus 1 may be used not only for a portable electronic device such as a mobile phone, a smartphone, a tablet personal computer (PC), a mobile communication terminal, an electronic organizer, an electronic book, a portable multimedia player (PMP), a navigation device, or an ultra-mobile PC (UMPC) but also for a display screen of various products such as a television, a laptop computer, a monitor, a billboard, or an Internet of things (IoT) product. Also, the display apparatus 1 according to an embodiment may be used in a wearable device such as a smart watch, a watch phone, a glasses-type display, or a head-mounted display (HMD). Also, the display apparatus 1 according to an embodiment may be used as a center information display (CID) located on an instrument panel, a center fascia or a dashboard of a vehicle, a room mirror display replacing a side-view mirror of a vehicle, or a display screen located on the back of a front seat.

The display apparatus 1 may include a display area DA and a peripheral area PA positioned outside the display area DA. The display apparatus 1 may provide an image through an array of pixels PX that are arranged in the display area DA. The pixel PX may include a pixel circuit and a light-emitting element connected to the pixel circuit. An image may be provided by light emitted from the light-emitting element of the pixel PX. Because an area where an image is provided is determined by an arrangement of a plurality of light-emitting elements, the display area DA may be defined by the plurality of light-emitting elements. The display area DA may further include various signal wirings and power supply wirings electrically connected to the pixel circuits.

The peripheral area PA where an image is not provided may entirely or partially surround the display area DA. A driving circuit and various wirings for providing an electrical signal or power to the display area DA may be located in the peripheral area PA.

In an embodiment, the display area DA of the display apparatus 1 may have a circular or elliptical shape when viewed in a direction perpendicular to one surface thereof. For example, as shown in FIG. 1, the display area DA of the display apparatus 1 may have a circular shape in a plan view. The shape of the display apparatus 1 is not limited to a circular or elliptical shape, and may be any of various shapes such as a polygonal shape other than a quadrangular shape, or an irregular shape.

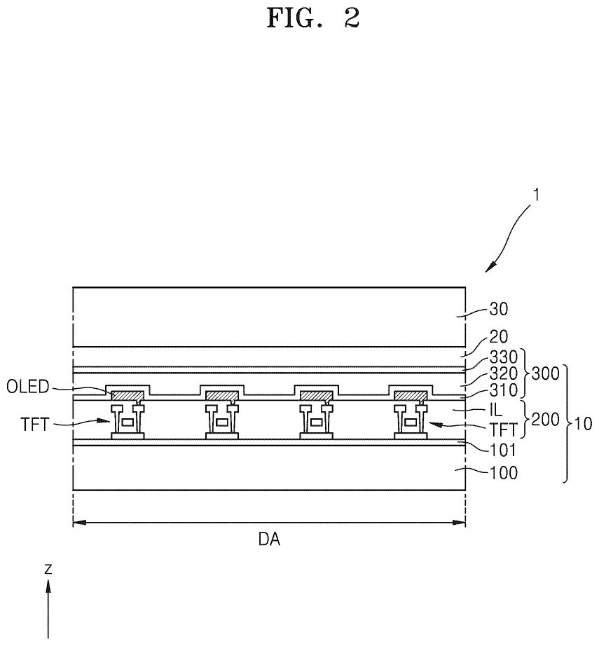

FIG. 2 is a cross-sectional view schematically illustrating the display apparatus 1. FIG. 2 is a cross-sectional view schematically illustrating the display area DA in the display apparatus 1.

Referring to FIG. 2, the display apparatus 1 may include a display panel 10 and a touch sensing unit 20 disposed on the display panel 10. In an embodiment, the display apparatus 1 may further include an optical functional layer 30 disposed on the touch sensing unit 20.

The display panel 10 may include a substrate 100, a display layer 200 disposed on the substrate 100, and an encapsulation member 300 on the display layer 200.

The substrate 100 may include glass or a polymer resin. Examples of the polymer resin may include polyethersulfone, polyacrylate, polyether imide, polyethylene naphthalate, polyethylene terephthalate, polyphenylene sulfide, polyarylate, polyimide, polycarbonate, and cellulose acetate propionate. The substrate 100 including a polymer resin may be flexible, rollable, or bendable. The substrate 100 may have a multi-layer structure including the polymer resin and an inorganic layer (not shown).

The display layer 200 may be disposed on the substrate 100. The display layer 200 may include a thin-film transistor TFT, a display element electrically connected to the thin-film transistor TFT, and an insulating layer IL. Although the display layer 200 includes an organic light-emitting diode OLED as a display element in FIG. 2, this is only an example and the present disclosure is not limited thereto. For example, the display apparatus 1 may include, as a display element, an organic light-emitting diode OLED including an organic emission layer, an inorganic light-emitting diode including an inorganic emission layer, or a quantum dot light-emitting diode including a quantum dot emission layer. For convenience of explanation, the following will be described assuming that the display apparatus 1 includes the organic light-emitting diode OLED.

The encapsulation member 300 may be disposed on the display layer 200. The encapsulation member 300 may include at least one inorganic encapsulation layer and at least one organic encapsulation layer. In an embodiment, the encapsulation member 300 may include first and second inorganic encapsulation layers 310 and 330, and an organic encapsulation layer 320 between the first and second inorganic encapsulation layers 310 and 330.

The touch sensing unit 20 may obtain coordinate information where an external input, for example, a touch event, is received. The touch sensing unit 20 may include a plurality of touch electrodes and signal lines connected to the plurality of touch electrodes. A touch sensor included in the touch sensing unit 20 may detect an external input by using, for example, a mutual capacitance method or a self-capacitance method.

Although the touch sensing unit 20 is provided as a separate element disposed on the display panel 10 in FIG. 2, the disclosure is not limited thereto. In an embodiment, the touch sensing unit 20 may be formed separately from the display panel 10 and may be attached to the display panel 10 by using an adhesive layer such as an optically clear adhesive (OCA). In an embodiment, the touch sensing unit 20 may be embedded in the display panel 10. For example, the touch sensing unit 20 may be formed directly on the encapsulation member 300 of the display panel 10, and an adhesive layer may not be interposed between the encapsulation member 300 and the touch sensing unit 20.

The optical functional layer 30 may be formed on the touch sensing unit 20. The optical functional layer 30 may include an anti-reflection layer. The anti-reflection layer may reduce a reflectance of light (external light) incident to the display apparatus 1.

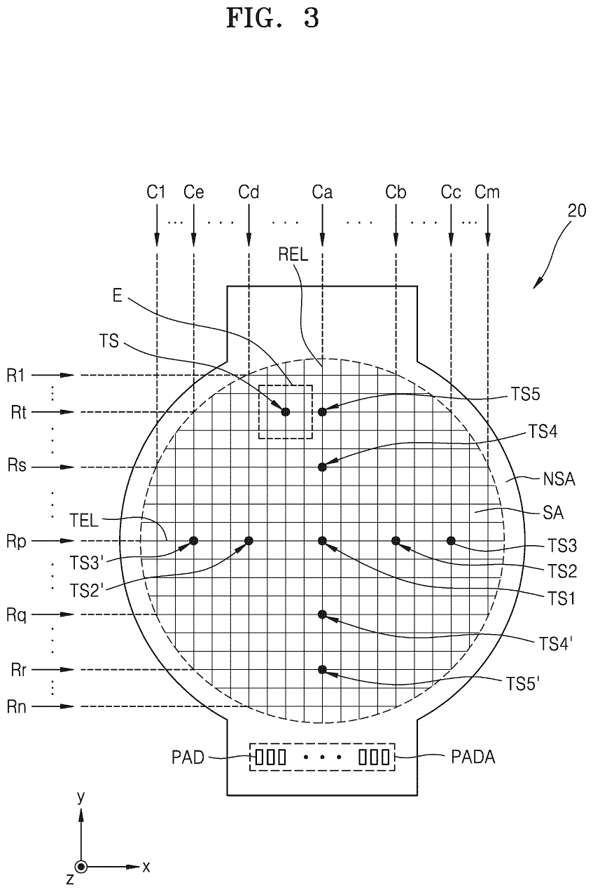

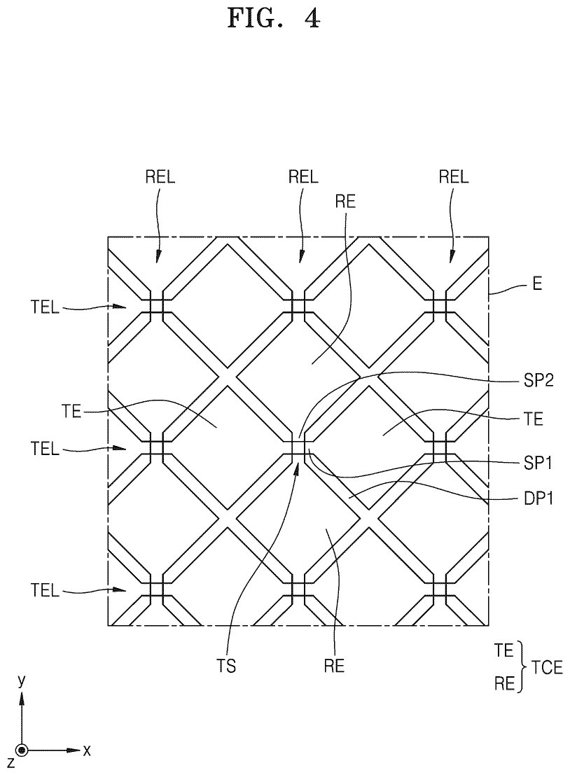

FIG. 3 is a plan view schematically illustrating the touch sensing unit 20 included in the display apparatus 1. FIG. 4 is an enlarged view schematically illustrating a portion ‘E’ of FIG. 3.

Referring to FIGS. 3 and 4, the touch sensing unit 20 may include a touch active area SA and a touch inactive area NSA positioned around the touch active area SA. The touch active area SA may overlap the display area DA of the display apparatus 1, and the touch inactive area NSA may overlap the peripheral area PA of the display apparatus 1. The touch active area SA may have a similar or identical shape to the display area DA. In an embodiment, the touch active area SA may have a circular shape, like the display area DA which has a circular shape, in a plan view. A shape of the touch active area SA is not limited thereto, and the touch active area SA may have any of various shapes such as a polygonal shape other than a quadrangular shape, a circular shape, an elliptical shape, or an irregular shape.

The touch active area SA may be an area for sensing an input applied from the outside. The input applied from the outside may be provided in various ways. For example, the input applied from the outside may include various types of external inputs such as a user's finger touch, a stylus pen, light, heat, or pressure. Also, the input applied from the outside may include an input applied at a place close to the display apparatus (e.g., hovering) as well as an input that contacts the display apparatus (e.g., a touch by the user's finger).

The touch sensing unit 20 may include driving electrode lines TEL and sensing electrode lines REL disposed in the touch active area SA. Each of the driving electrode lines TEL may extend in a first direction (e.g., an x direction). The driving electrode lines TEL may be spaced apart from each other in a second direction (e.g., a y direction) crossing the first direction (e.g., the x direction). Each of the sensing electrode lines REL may extend in the second direction (e.g., the y direction). The sensing electrode lines REL may be spaced apart from each other in the first direction (e.g., the x direction).

The first direction (e.g., the x direction) in which the driving electrode line TEL extends and the second direction (e.g., the y direction) in which the sensing electrode line REL extends may be different directions intersecting each other. For example, when a row direction is referred to as the first direction (e.g., the x direction), the second direction (e.g., the y direction) may be a column direction. For example, the driving electrode lines TEL may be arranged in a first row R1 to an n^{th} row Rn, and the sensing electrode lines REL may be arranged in a first column C1 to an m^{th} column Cm (each of n and m is a natural number equal to or greater than 3). For convenience of explanation, the following will be described assuming that the driving electrode line TEL extends in a row direction and the sensing electrode line REL extends in a column direction. The number of driving electrode lines TEL and the number of sensing electrode lines REL may be changed in various ways according to embodiments. For convenience of explanation, the following will be described assuming that each of n and m is 7 or more as shown in FIG. 3.

In an embodiment, the driving electrode lines TEL may include at least two driving electrode lines TEL having different lengths. For example, a length of the driving electrode line TEL disposed in a p^{th} row Rp may be greater than that of the driving electrode line TEL disposed in a q^{th} row Rq.

In an embodiment, when the touch active area SA has a circular shape as shown in FIG. 3, a length of the driving electrode line TEL positioned in the p^{th} row Rp, which is a center row of the first row R1 to the n^{th} row Rn, is the largest, and a length of the driving electrode line TEL may decrease as the driving electrode line TEL gets away from the center. That is, a length of the driving electrode line TEL may decrease as the driving electrode TEL gets closer to the touch inactive area NSA. For example, a length of the driving electrode line TEL disposed in the p^{th} row Rp may be greater than a length of the driving electrode line TEL disposed in the s^{th} row Rs, and a length of the driving electrode line TEL disposed in the s^{th} row Rs may be greater than a length of the driving electrode line TEL disposed in a t^{th} row Rt (p, s, and t are different natural numbers equal to or less than n). In an embodiment, the s^{th} row may be a row positioned between the first row R1 and the p^{th} row Rp, and the t^{th} row Rt may be a row positioned between the first row R1 and the s^{th} row Rs. Likewise, for example, a length of the driving electrode line TEL disposed in the p^{th} row Rp may be greater than a length of the driving electrode line TEL disposed in the q^{th} row Rq, and a length of the driving electrode line TEL disposed in the q^{th} row Rq may be greater than a length of the driving electrode line TEL disposed in the r^{th} row Rr (p, q, and r are different natural numbers equal to or less than n). In an embodiment, the q^{th} row may be a row positioned between the p^{th} row Rp and the n^{th} row Rn, and the r^{th} row Rr may be a row positioned between the q^{th} row Rq and the n^{th} row Rn.

In an embodiment, when the touch active area SA has a circular shape as shown in FIG. 3, lengths of the driving electrode lines TEL positioned in two rows spaced apart by the same distance from the p^{th} row Rp, which is a center row, may be substantially the same. For example, the s^{th} row Rs and the q^{th} row Rq may be spaced apart by the same distance from the p^{th} row Rp, and a length of the driving electrode line TEL disposed in the s^{th} row Rs may be substantially the same as a length of the driving electrode line TEL disposed in the q^{th} row Rq. For example, the t^{th} row Rt and the r^{th} row Rr may be spaced apart by the same distance from the p^{th} row Rp, and a length of the driving electrode line TEL positioned in the t^{th} row Rt may be substantially the same as a length of the driving electrode line TEL positioned in the r^{th} row Rr.

In an embodiment, the sensing electrode lines REL may include at least two sensing electrode lines REL having different lengths. For example, a length of the sensing electrode line REL disposed in an a^{th} column Ca may be greater than a length of the sensing electrode line REL disposed in a b^{th} column Cb.

In an embodiment, when the touch active area SA has a circular shape as shown in FIG. 3, a length of the sensing electrode line REL located in the a^{th} column Ca, which is a center column among the first column C1 to the m^{th} column Cm, may be the largest, and a length of the sensing electrode line REL may decrease as the sensing electrode line REL gets away from the center. That is, a length of the sensing electrode line REL may decrease as the sensing electrode line REL gets closer to the touch inactive area NSA. For example, a length of the sensing electrode line REL positioned in the a^{th} column Ca may be greater than a length of the sensing electrode line REL positioned in the b^{th} column Cb, and a length of the sensing electrode line REL disposed in the b^{th} column Cb may be greater than a length of the sensing electrode line REL disposed in a c^{th} column Cc (a, b, and c are different natural numbers equal to or less than n). In an embodiment, the c^{th} column Cc may be a column positioned between the a^{th} column Ca and the m^{th} column Cm, and the b^{th} column Cb may be a column positioned between the a^{th} column Ca and the c^{th} column Cc. Likewise, for example, a length of the sensing electrode line REL disposed in the a^{th} column Ca may be greater than a length of the sensing electrode line REL disposed in a d^{th} column Cd, and a length of the sensing electrode line REL disposed in the d^{th} column Cd may be greater than a length of the sensing electrode line REL disposed in an eth column Ce (a, d, and e are different natural numbers equal to or less than n). In an embodiment, the d^{th} column Cd may be a column positioned between the first column C1 and the a^{th} column Ca, and the eth column Ce may be a column positioned between the first column C1 and the d^{th} column Cd.

In an embodiment, when the touch active area SA has a circular shape as shown in FIG. 3, lengths of the sensing electrode lines REL disposed in two columns spaced apart by the same distance from the a^{th} column Ca, which is a center column, may be substantially the same. For example, the b^{th} column Cb and the d^{th} column Cd may be spaced apart by the same distance from the a^{th} column Ca, and a length of the sensing electrode line REL disposed in the b^{th} column Cb may be substantially the same as a length of the sensing electrode line REL disposed in the d^{th} column Cd. For example, the c^{th} column Cc and the eth column Ce may be spaced apart by the same distance from the a^{th} column Ca, and a length of the sensing electrode line REL disposed in the c^{th} column Cc may be substantially the same as a length of the sensing electrode line REL disposed in the eth column Ce.

The driving electrode lines TEL may include a plurality of driving electrodes TE and a plurality of first connection patterns SP1, as shown in FIG. 4. The driving electrodes TE included in each of the driving electrode lines TEL may be arranged in the first direction (e.g., the x direction). The driving electrodes TE included in each driving electrode line TEL (i.e., the driving electrodes TE positioned in the same row) may be connected by the first connection patterns SP1 extending along the same row. That is, the first connection pattern SP1 may be disposed between two driving electrodes TE adjacent to each other in the first direction (e.g., the x direction).

The sensing electrode lines REL may include a plurality of sensing electrodes RE and a plurality of second connection patterns SP2, as shown in FIG. 4. The sensing electrodes RE included in each of the sensing electrode lines REL may be arranged in the second direction (e.g., the y direction). The sensing electrodes RE included in each sensing electrode line REL (i.e., the sensing electrodes RE positioned in the same column) may be connected by the second connection patterns SP2 extending along the same column. That is, the second connection pattern SP2 may be disposed between two sensing electrodes RE adjacent to each other in the second direction (e.g., the y direction).

The touch sensing unit 20 may include a plurality of touch sensors TS located in the touch active area SA. The touch sensors TS may be positioned at intersections between the driving electrode lines TEL and the sensing electrode lines REL. Because the touch sensors TS are positioned at intersections between the driving electrode lines TEL, which extend in the row direction, and the sensing electrode lines REL, which extend in the column direction, the touch sensors TS may be arranged in a matrix of first to n^{th} rows and first to m^{th} columns. Each of the touch sensors TS may be positioned at an intersection between the first connection pattern SP1 and the second connection pattern SP2.

Each of the touch sensors TS may include the first connection pattern SP1, the second connection pattern SP2, and a touch electrode TCE. The touch electrode TCE may include the driving electrodes TE and the sensing electrodes RE. The touch electrode TCE included in each of the touch sensors TS may include the driving electrodes TE positioned at left and right sides of the first connection pattern SP1 and the sensing electrodes RE positioned at upper and lower sides of the second connection pattern SP2. Each of the touch sensors TS may detect an external touch through the driving electrodes TE and the sensing electrodes RE each of which is positioned adjacent to an area where the first connection pattern SP1 and the second connection pattern SP2 overlap.

The numbers of touch sensors TS arranged in at least two different rows may be different from each other. For example, the number of touch sensors TS disposed in the p^{th} row Rp may be greater than the number of touch sensors TS in the q^{th} row Rq.

In an embodiment, when the touch active area SA has a circular shape as shown in FIG. 3, the number of touch sensors TS arranged in the p^{th} row Rp, which is a center row among the first row R1 to the n^{th} row Rn, may be the largest, and the number of touch sensors TS arranged in a row may decrease as the row where the touch sensors TS are positioned gets away from the p^{th} row Rp. That is, the number of touch sensors TS may decrease as the touch sensors TS gets closer to the touch inactive area NSA. For example, the number of touch sensors TS arranged in the p^{th} row Rp may be greater than the number of touch sensors TS arranged in the s^{th} row Rs, and the number of touch sensors TS arranged in the s^{th} row Rs may be greater than the number of touch sensors TS arranged in the t^{th} row Rt (p, s, and t are different natural numbers equal to or less than n). In an embodiment, the s^{th} row may be a row positioned between the first row R1 and the p^{th} row Rp, and the t^{th} row Rt may be a row positioned between the first row R1 and the s^{th} row Rs. Likewise, for example, the number of touch sensors TS arranged in the p^{th} row Rp may be greater than the number of touch sensors TS arranged in the q^{th} row Rq, and the number of touch sensors TS arranged in the q^{th} row Rq may be greater than the number of touch sensors TS arranged in the r^{th} row Rr (p, q, and r are different natural numbers equal to or less than n). In an embodiment, the q^{th} row may be a row positioned between the p^{th} row Rp and the n^{th} row Rn, and the r^{th} row Rr may be a row positioned between the q^{th} row Rq and the n^{th} row Rn.

In an embodiment, when the touch active area SA has a circular shape as shown in FIG. 3, the numbers of touch sensors TS arranged in two rows spaced apart by the same distance from the p^{th} row Rp, which is a center row, may be the same. For example, the s^{th} row Rs and the q^{th} row Rq may be spaced apart by the same distance from the p^{th} row Rp, and the number of touch sensors TS arranged in the s^{th} row Rs may be the same as the number of touch sensors TS arranged in the q^{th} row Rq. For example, the t^{th} row Rt and the r^{th} row Rr may be spaced apart by the same distance from the p^{th} row Rp, and the number of touch sensors TS arranged in the t^{th} row Rt may be the same as the number of touch sensors TS arranged in the r^{th} row Rr.

The numbers of touch sensors TS located in at least two different columns may be different from each other. For example, the number of touch sensors TS arranged in the a^{th} column Ca may be greater than the number of touch sensors TS arranged in the b^{th} column Cb.

In an embodiment, when the touch active area SA has a circular shape as shown in FIG. 3, the number of touch sensors TS arranged in the a^{th} column Ca, which is a center column among the first column C1 to the m^{th} column Cm, may be the largest, and the number of touch sensors TS arranged in a column may decrease as the column where the touch sensors TS are arranged gets away from the a^{th} column Ca. That is, the number of touch sensors TS may decrease as the touch sensors TS gets closer to the touch inactive area NSA. For example, the number of touch sensors TS arranged in the a^{th} column Ca may be greater than the number of touch sensors TS arranged in the b^{th} column Cb, and the number of touch sensors TS arranged in the b^{th} column Cb may be greater than the number of touch sensors TS arranged in the c^{th} column Cc (a, b, and c are different natural numbers equal to or less than n). In an embodiment, the c^{th} column Cc may be a column positioned between the a^{th} column Ca and the m^{th} column Cm, and the b^{th} column Cb may be a column positioned between the a^{th} column Ca and the c^{th} column Cc. Likewise, the number of touch sensors TS arranged in the a^{th} column Ca may be greater than the number of touch sensors TS arranged in the d^{th} column Cd, and the number of touch sensors TS arranged in the d^{th} column Cd may be greater than the number of touch sensors TS arranged in the eth column Ce (a, d, and e are different natural numbers equal to or less than n). In an embodiment, the d^{th} column Cd may be a column positioned between the first column C1 and the a^{th} column Ca, and the e^{th} column Ce may be a column positioned between the first column C1 and the d^{th} column Cd.

In an embodiment, when the touch active area SA has a circular shape as shown in FIG. 3, the numbers of touch sensors TS arranged in two columns spaced apart by the same distance from the a^{th} column Ca, which is a center column, may be the same. For example, the b^{th} column Cb and the d^{th} column Cd may be spaced apart by the same distance from the a^{th} column Ca, and the number of touch sensors TS arranged in the b^{th} column Cb may be the same as the number of touch sensors TS arranged in the d^{th} column Cd. For example, the c^{th} column Cc and the e^{th} column Ce may be spaced apart by the same distance from the a^{th} column Ca, and the number of touch sensors TS arranged in the c^{th} column Cc may be the same as the number of touch sensors TS arranged in the e^{th} column Ce.

The touch sensing unit 20 may include driving signal wirings disposed in the touch inactive area NSA and connected in a one-to-one manner to the driving electrode lines TEL. Each of the driving signal wirings may electrically connect the driving electrode line and a pad PAD disposed in a pad area PADA, which correspond to each other.

The touch sensing unit 20 may include sensing signal wirings disposed in the touch inactive area NSA and connected in a one-to-one manner to the sensing electrode lines REL. Each of the sensing signal wirings may electrically connect the sensing electrode line REL and the pad PAD disposed in the pad area PADA, which correspond to each other.

The touch sensing unit 20 may include the sensing signal wirings respectively connected to the sensing electrode lines REL. Each of the sensing signal wirings may electrically connect the sensing electrode line REL to the pad area PADA.

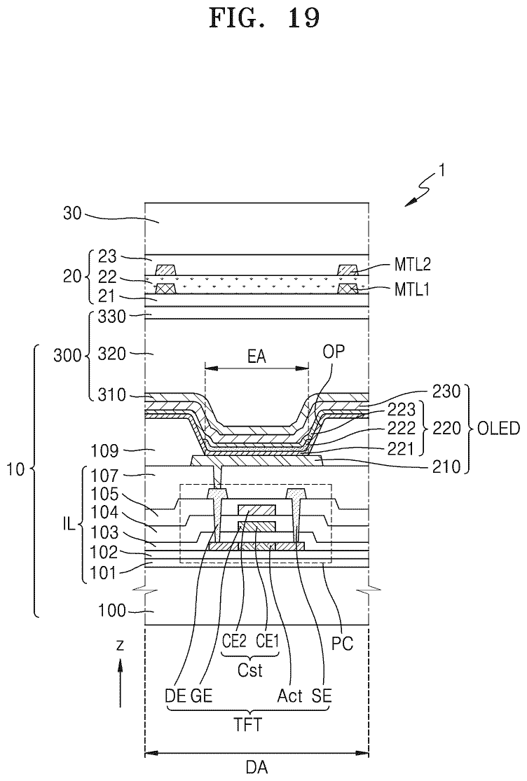

Parasitic capacitance may be formed between the touch electrodes TCE of the touch sensors TS and a counter electrode 230 (see FIG. 19) described below. When the areas of the touch electrodes TEC included in the touch sensor TS are the same, as shown in FIG. 3, because the numbers of touch sensors TS arranged in columns (or rows) are different from each other, parasitic capacitance values formed between the touch electrodes TCE of the touch sensors TS arranged in columns (or rows) and the counter electrode 230 are different from each other. For example, when the areas of the touch electrodes TCE included in the touch sensors TS are the same, a parasitic capacitance value in the a^{th} column Ca including more touch sensors TS than other columns is different from a parasitic capacitance value in the b^{th} column Cb including fewer touch sensors TS. When parasitic capacitance values are different from each other depending on rows (or columns) where the touch electrodes TCE are arranged, touch malfunction may occur.

According to embodiments of the present disclosure, a difference of parasitic capacitance values in separate columns (or rows) may be reduced by forming the touch electrodes TCE of the touch sensors TS arranged in different rows or different columns to have different areas. Accordingly, a display apparatus according to embodiments of the present disclosure may prevent or reduce touch malfunction. Hereinafter, embodiments of the touch sensors TS will be described in more detail.

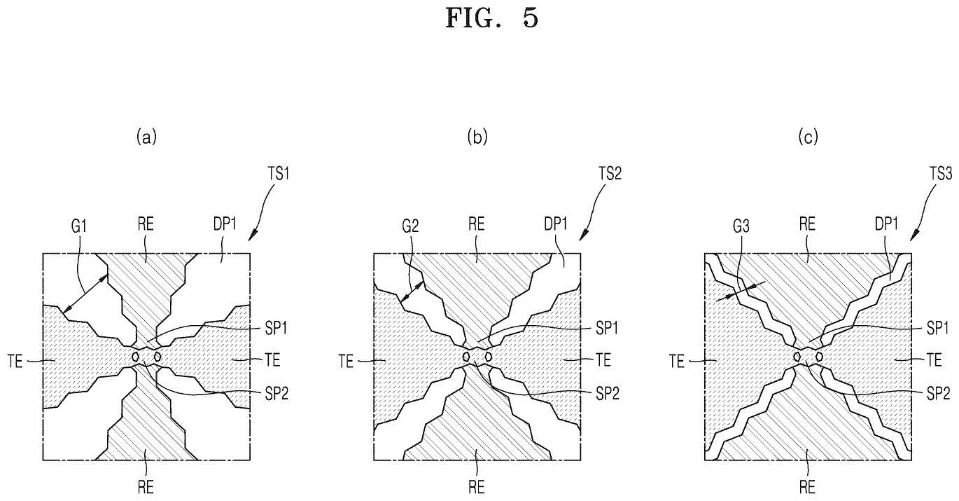

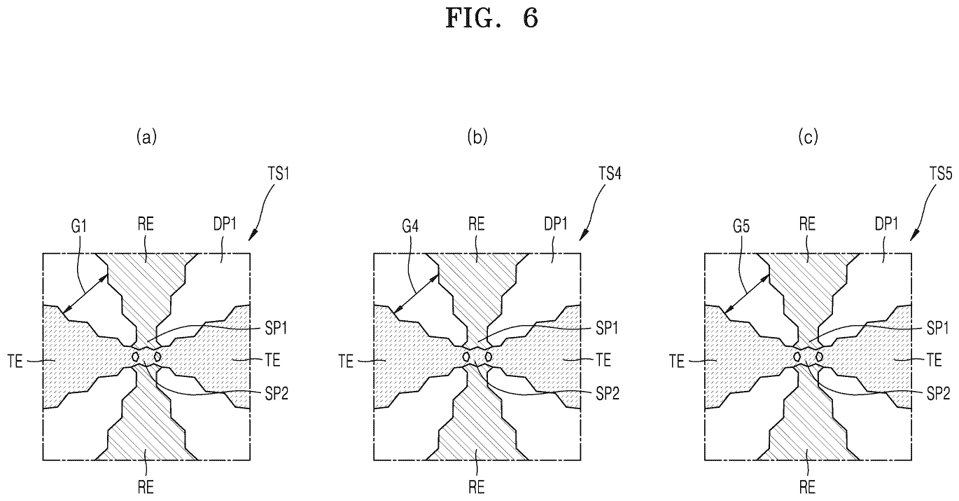

FIGS. 5 and 6 are enlarged views schematically illustrating touch sensors located at different positions illustrated in FIG. 3.

FIG. 5 is enlarged views respectively illustrating a first touch sensor TS1, a second touch sensor TS2, and a third touch sensor TS3 of FIG. 3, according to an embodiment. The first touch sensor TS1, the second touch sensor TS2, and the third touch sensor TS3 are arranged in the same row but are positioned in different columns. In detail, the first touch sensor TS1 may be disposed at an intersection between the a^{th} column Ca and the p^{th} row Rp, the second touch sensor TS2 may be disposed at an intersection between the b^{th} column Cb and the p^{th} row Rp, and the third touch sensor TS3 may be disposed at an intersection between the c^{th} column Cc and the p^{th} row Rp.

FIG. 6is enlarged views respectively illustrating the first touch sensor TS1, a fourth touch sensor TS4, and a fifth touch sensor TS5 of FIG. 3, according to an embodiment. The first touch sensor TS1, the fourth touch sensor TS4, and the fifth touch sensor TS5 are arranged in the same column but are positioned in different rows. In detail, the first touch sensor TS1 may be disposed at an intersection between the a^{th} column Ca and the p^{th} row Rp, the fourth touch sensor TS4 may be disposed at an intersection between the a^{th} column Ca and the s^{th} row Rs, and the fifth touch sensor TS5 may be disposed at an intersection between the a^{th} column Ca and the t^{th} row Rt.

Referring to FIGS. 3 to 6, the areas of the touch electrodes TCE of the touch sensors TS disposed in different columns may be different from each other, and the areas of the touch electrodes TCE of the touch sensors TS disposed in different rows in each column may be the same.

The unit area of the touch sensor TS disposed at an edge (or corner) of the touch active area SA may be less than the unit area of the touch sensor TS disposed at the center of the touch active area SA. The specification will be described by comparing the areas of the touch electrodes TCE of the touch sensors TS having the same unit area. That is, the unit areas of the touch sensors TS of the specification may be the same.

In an embodiment, the area of the touch electrode TCE of the touch sensor TS arranged in a column in which the sensing electrode line REL having a relatively large length is located may be less than the area of the touch electrode TCE of the touch sensor TS arranged in a column in which the sensing electrode line REL having a relatively small length is located. In other words, the area of the touch electrode TCE of the touch sensor TS disposed in a column in which more touch sensors TS are arranged may be less than the area of the touch electrode TCE of the touch sensor TS disposed in a column in which fewer touch sensors TS are arranged.

The area of the touch electrode TCE of the first touch sensor TS1 arranged in the a^{th} column Ca may be less than the area of the touch electrode TCE of the second touch sensor TS2 arranged in the b^{th} column Cb. The area of the driving electrode TE of the first touch sensor TS1 arranged in the a^{th} column Ca may be less than the area of the driving electrode TE of the second touch sensor TS2 arranged in the b^{th} column Cb. The area of the sensing electrode RE of the first touch sensor TS1 arranged in the a^{th} column Ca may be less than the area of the sensing electrode RE of the second touch sensor TS2 arranged in the b^{th} column Cb.

The area of the touch electrode TCE of the second touch sensor TS2 arranged in the b^{th} column Cb may be less than the area of the touch electrode TCE of the third touch sensor TS3 arranged in the c^{th} column Cc. The area of the driving electrode TE of the second touch sensor TS2 arranged in the b^{th} column Cb may be less than the area of the driving electrode TE of the third touch sensor TS3 arranged in the c^{th} column Cc. The area of the sensing electrode RE of the second touch sensor TS2 arranged in the b^{th} column Cb may be less than the area of the sensing electrode RE of the third touch sensor TS3 arranged in the c^{th} column Cc.

Each touch sensor TS may further include a first dummy pattern DP1 positioned between the driving electrode TE and the sensing electrode RE. In an embodiment, the area of the first dummy pattern DP1 arranged in a column in which the sensing electrode line REL having a relatively large length is located may be greater than the area of the first dummy pattern DP1 of the touch sensor TS arranged in a column in which the sensing electrode line REL having a relatively small length is located. In other words, the area of the first dummy pattern DP1 of the touch sensor TS arranged in a column in which more touch sensors TS are located may be greater than the area of the first dummy pattern DP1 of the touch sensor TS arranged in a column in which fewer touch sensors TS are located. In an embodiment, an interval between the driving electrode TE and the sensing electrode RE of the touch sensor TS arranged in a column in which more touch sensors TS are located may be greater than an interval between the driving electrode TE and the sensing electrode RE of the touch sensor TS arranged in a column in which fewer touch sensors TS are located.

The area of the first dummy pattern DP1 of the first touch sensor TS1 may be greater than the area of the first dummy pattern DP1 of the second touch sensor TS2. In an embodiment, in a plan view, an interval G1 between the driving electrode TE and the sensing electrode RE of the first touch sensor TS1 may be greater than an interval G2 between the driving electrode TE and the sensing electrode RE of the second touch sensor TS2. In the specification, an interval between ‘A’ and ‘B’ is defined as an average interval between ‘A’ and ‘B’.

The area of the first dummy pattern DP1 of the second touch sensor TS2 may be greater than the area of the first dummy pattern DP1 of the third touch sensor TS3. In a plan view, the interval G2 between the driving electrode TE and the sensing electrode RE of the second touch sensor TS2 may be greater than an interval G3 between the driving electrode TE and the sensing electrode RE of the third touch sensor TS3.

In an embodiment, the areas or shapes of the touch electrodes TCE of the touch sensors TS arranged in columns in which the sensing electrode lines REL having the same length are located may be substantially the same. In other words, the areas or shapes of the touch electrodes TCE of the touch sensors TS arranged in columns in which the same number of touch sensors TS are located may be substantially the same. For example, the area of the touch electrode TCE of the second touch sensor TS2 arranged in the b^{th} column Cb may be substantially the same as the area of the touch electrode TCE of a 2-1 touch sensor TS2′ arranged in the d^{th} column Cd. For example, the area of the touch electrode TCE of the third touch sensor TS3 arranged in the c^{th} column Cc may be substantially the same as the area of the touch electrode TCE of a 3-1 touch sensor TS3′ arranged in the e^{th} column Ce.

In an embodiment, the areas of the touch sensors TS located in different rows in each column may be substantially the same. In an embodiment, the areas of the first touch sensor TS1, the fourth touch sensor TS4, and the fifth touch sensor TS5 arranged in the same column may be substantially the same.

The area of the driving electrode TE of the first touch sensor TS1 arranged in the a^{th} column Ca and the p^{th} row Rp may be substantially the same as the area of the driving electrode TE of the fourth touch sensor TS4 arranged in the a^{th} column and the s^{th} row Rs. The area of the sensing electrode RE of the first touch sensor TS1 arranged in the a^{th} column Ca and the p^{th} row Rp may be substantially the same as the area of the sensing electrode RE of the fourth touch sensor TS4 arranged in the a^{th} column and the s^{th} row Rs.

The area of the driving electrode TE of the fourth touch sensor TS4 arranged in the a^{th} column Ca and the s^{th} row Rs may be substantially the same as the area of the driving electrode TE of the fifth touch sensor TS5 arranged in the a^{th} column Ca and the t^{th} row Rt. The area of the sensing electrode RE of the fourth touch sensor TS4 arranged in the a^{th} column Ca and the s^{th} row Rs may be substantially the same as the area of the sensing electrode RE of the fifth touch sensor TS5 arranged in the a^{th} column Ca and the t^{th} row Rt.

The area of the first dummy pattern DP1 of the first touch sensor TS1 may be substantially the same as the area of the first dummy pattern DP1 of the fourth touch sensor TS4. In a plan view, the interval G1 between the driving electrode TE and the sensing electrode RE of the first touch sensor TS1 may be substantially the same as an interval G4 between the driving electrode TE and the sensing electrode RE of the fourth touch sensor TS4.

The area of the first dummy pattern DP1 of the fourth touch sensor TS4 may be substantially the same as the area of the first dummy pattern DP1 of the fifth touch sensor TS5. In a plan view, the interval G4 between the driving electrode TE and the sensing electrode RE of the fourth touch sensor TS4 may be substantially the same as an interval G5 between the driving electrode TE and the sensing electrode RE of the fifth touch sensor TS5.

In an embodiment, the areas or shapes of the touch electrodes TCE of the touch sensors TS arranged in rows in which the driving electrodes TEL having the same length are located may be substantially the same. In other words, the areas or shapes of the touch electrodes TCE of the touch sensors TS arranged in rows in which the same number of touch sensors TS are located may be substantially the same. For example, the area of the touch electrode TCE of the fourth touch sensor TS4 arranged in the s^{th} row Rs may be substantially the same as the area of the touch electrode TCE of a 4-1 touch sensor TS4′ arranged in the q^{th} row Rq. For example, the area of the touch electrode TCE of the fifth touch sensor TS5 arranged in the t^{th} row Rt may be substantially the same as the area of the touch electrode TCE of a 5-1 touch sensor TS5′ arranged in the r^{th} row Rr. Accordingly, the touch electrodes TCE of the first touch sensor TS1, the fourth touch sensor TS4, the fifth touch sensor TS5, the 4-1 touch sensor TS4′, and the 5-1 touch sensor TS5′ arranged in the same column may have substantially the same area.

Although the first touch sensor TS1, the fourth touch sensor TS4, and the fifth touch sensor TS5 arranged in the a^{th} column Ca are described in FIG. 6, the disclosure is not limited thereto. For example, the touch sensors TS arranged in different rows in another column may also have substantially the same area. For example, the second touch sensor TS2 located in the b^{th} column Cb and the p^{th} row may have substantially the same area as those of a touch sensor located in the b^{th} column Cb and the s^{th} row Rs and of a touch sensor located in the b^{th} column Cb and the t^{th} row Rt.

In an embodiment of FIGS. 5 and 6, because the area of the touch electrode TCE in a column in which more touch sensors TS are arranged (e.g., the a^{th} column Ca) is smaller than the area of the touch electrode TCE in a column in which fewer touch sensors TS are arranged (e.g., the b^{th} column Cb), a difference in parasitic capacitance values may be reduced.

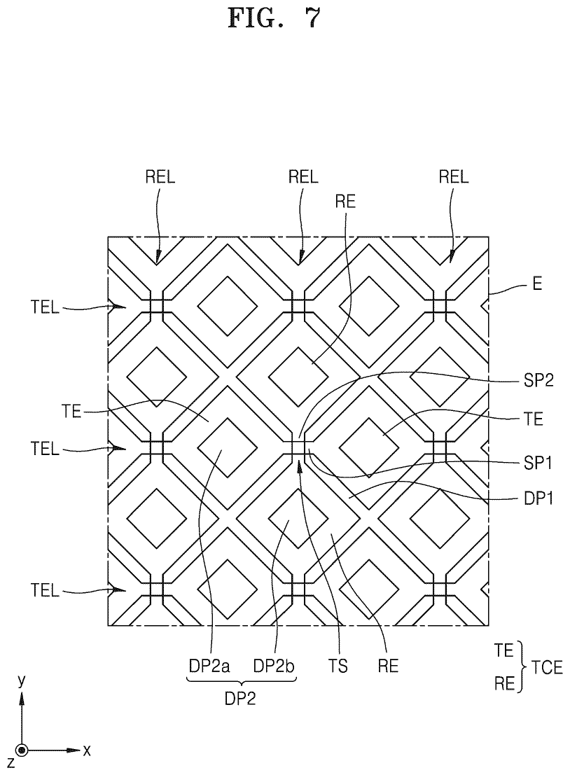

FIG. 7 is an enlarged view schematically illustrating the portion ‘E’ of FIG. 3, according to an embodiment.

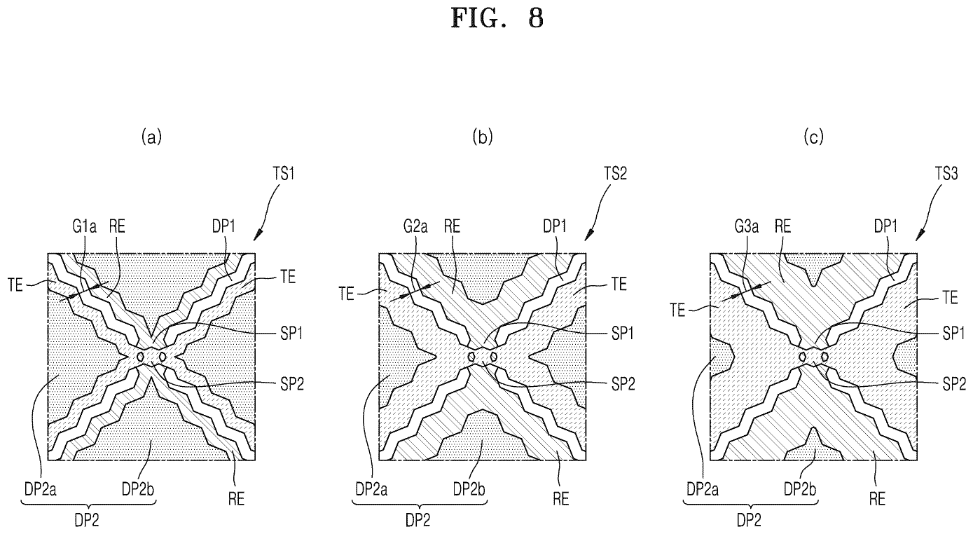

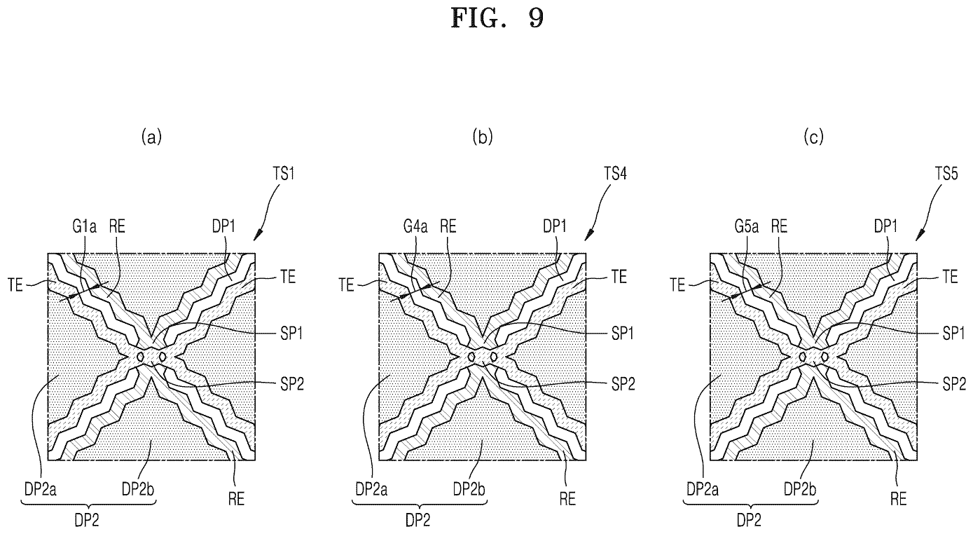

FIGS. 8 and 9 are enlarged views schematically illustrating touch sensors located at different positions illustrated in FIG. 3. FIG. 8 is enlarged views respectively illustrating the first touch sensor TS1, the second touch sensor TS2, and the third touch sensor TS3. FIG. 9 is enlarged views respectively illustrating the first touch sensor TS1, the fourth touch sensor TS4, and the fifth touch sensor TS5 of FIG. 3.

In an embodiment described with reference to FIGS. 8 and 9, the areas of the touch electrodes TCE of the touch sensors TS arranged in different columns may be different from each other, like an embodiment described with reference to FIGS. 3 to 6. Also, the areas of the touch electrodes TCE of the touch sensors TS arranged in different rows in each column may be the same. An embodiment described with reference to FIGS. 8 and 9 is a modified example of an embodiment described with reference to FIGS. 3 to 6, and thus, a repeated description will be omitted and a difference will be mainly described.

Referring to FIGS. 3, 7, 8, and 9, at least some of the touch sensors TS may further include a second dummy pattern DP2 located inside the touch electrode TCE. The second dummy pattern DP2 may include a 2-1 dummy pattern DP2a located inside the driving electrode TE and a 2-2 dummy pattern DP2b located inside the sensing electrode RE. In an embodiment, each of the driving electrode TE and the sensing electrode RE may have a ring shape surrounding the second dummy pattern DP2 located therein.

In an embodiment, the area of the second dummy pattern DP2 of the touch sensor TS arranged in a column in which the sensing electrode line REL having a relatively large length is located may be greater than the area of the second dummy pattern DP2 of the touch sensor TS arranged in a column in which the sensing electrode line REL having a relatively small length is located. In other words, the area of the second dummy pattern DP2 of the touch sensor TS arranged in a column in which more touch sensors TS are located may be greater than the area of the second dummy pattern DP2 of the touch sensor TS arranged in a column in which fewer touch sensors TS are located. Accordingly, the area of the touch electrode TCE of the touch sensor TS arranged in a column in which more touch sensors TS are located may be less than the area of the touch electrode TCE of the touch sensor TS arranged in a column in which fewer touch sensors TS are located.

The area of the second dummy pattern DP2 of the first touch sensor TS1 arranged in the a^{th} column Ca may be greater than the area of the second dummy pattern DP2 of the second touch sensor TS2 arranged in the b^{th} column Cb. The area of the 2-1 dummy pattern DP2a of the first touch sensor TS1 may be greater than the area of the 2-1 dummy pattern DP2a of the second touch sensor TS2. The area of the 2-2 dummy pattern DP2b of the first touch sensor TS1 may be greater than the area of the 2-2 dummy pattern DP2b of the second touch sensor TS2.

The area of the second dummy pattern DP2 of the second touch sensor TS2 arranged in the b^{th} column Cb may be greater than the area of the second dummy pattern DP2 of the third touch sensor TS3 arranged in the c^{th} column Cc. The area of the 2-1 dummy pattern DP2a of the second touch sensor TS2 may be greater than the area of the 2-1 dummy pattern DP2a of the third touch sensor TS3. The area of the 2-2 dummy pattern DP2b of the second touch sensor TS2 may be greater than the area of the 2-2 dummy pattern DP2b of the third touch sensor TS3.

As the area of the second dummy pattern DP2 of the first touch sensor TS1 is greater than the area of the second dummy pattern DP2 of the second touch sensor TS2, the area of the touch electrode TCE of the first touch sensor TS1 may be less than the area of the touch electrode TCE of the second touch sensor TS2. Likewise, as the area of the second dummy pattern DP2 of the second touch sensor TS2 is greater than the area of the second dummy pattern DP2 of the third touch sensor TS3, the area of the touch electrode TCE of the second touch sensor TS2 may be less than the area of the touch electrode TCE of the third touch sensor TS3.

Although each of the touch sensors TS includes the second dummy pattern DP2 as illustrated in FIGS. 7 and 8, the present disclosure is not limited thereto. In an embodiment, some touch sensors TS may not include the second dummy pattern DP2 and may have a non-ring shape. For example, the touch sensors TS in a column in which more touch sensors TS are located may include the second dummy pattern DP2, and the touch sensors TS in a column in which fewer touch sensors TS are located may not include the second dummy pattern DP2. For example, the area of the second dummy pattern DP2 of the first touch sensor TS1 may be greater than the area of the second dummy pattern DP2 of the second touch sensor TS2, and the third touch sensor TS3 may not include the second dummy pattern DP2.

In an embodiment, the areas of the second dummy patterns DP2 of the first touch sensor TS1, the fourth touch sensor TS4, and the fifth touch sensor TS5 arranged in the same column may be substantially the same.

The area of the 2-1 dummy pattern DP2a of the first touch sensor TS1, the area of the 2-1 dummy pattern DP2a of the fourth touch sensor TS4, and the area of the 2-1 dummy pattern DP2a of the fifth touch sensor TS5 may be substantially the same. The area of the 2-2 dummy pattern DP2b of the first touch sensor TS1, the area of the 2-2 dummy pattern DP2b of the fourth touch sensor TS4, and the area of the 2-2 dummy pattern DP2b of the fifth touch sensor TS5 may be substantially the same.

In an embodiment, an interval between the driving electrode and the sensing electrode RE of each of the touch sensors TS may be the same. For example, an interval G1a between the driving electrode TE and the sensing electrode RE of the first touch sensor TS1, an interval G2a between the driving electrode TE and the sensing electrode RE of the second touch sensor TS2, and an interval G3a between the driving electrode TE and the sensing electrode RE of the third touch sensor TS3 may be substantially the same. For example, the interval G1a between the driving electrode TE and the sensing electrode RE of the first touch sensor TS1, an interval G4a between the driving electrode TE and the sensing electrode RE of the fourth touch sensor TS4, and an interval G5a between the driving electrode TE and the sensing electrode RE of the fifth touch sensor TS5 may be substantially the same.

In other words, the areas of the first dummy patterns DP1 of the touch sensors TS may be substantially the same. For example, the areas of the first dummy patterns DP1 of the first touch sensor TS1, the second touch sensor TS2, and the third touch sensor TS3 may be substantially the same. For example, the areas of the first dummy patterns DP1 of the first touch sensor TS1, the fourth touch sensor TS4, and the fifth touch sensor TS5 may be substantially the same.

However, this is only an example, and the present disclosure is not limited thereto. In an embodiment, intervals between the driving electrodes TE and the sensing electrodes RE of the touch sensors TS located in different columns or different rows may be different from each other.

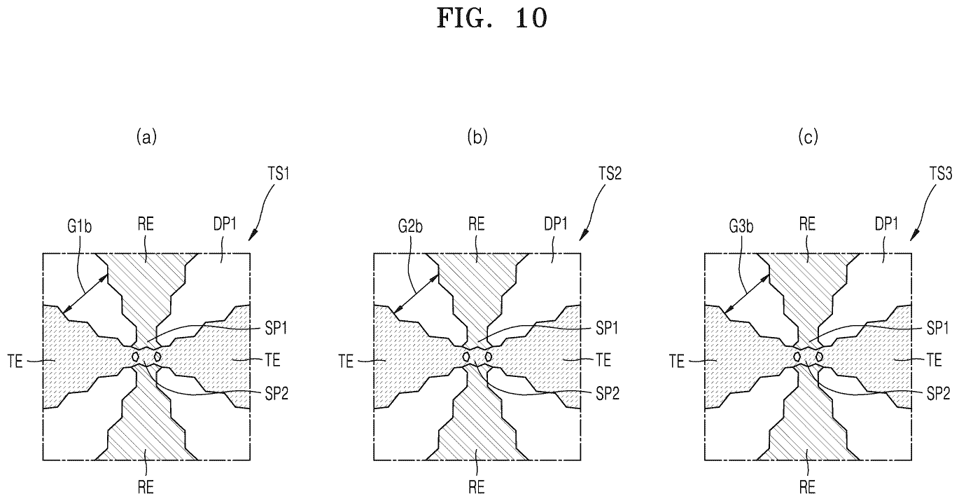

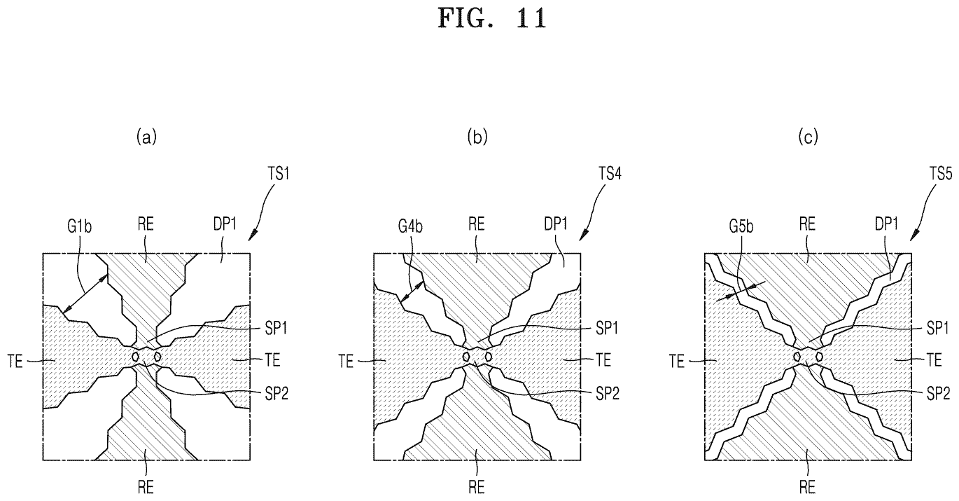

FIGS. 10 and 11 are enlarged views schematically illustrating touch sensors located at different positions illustrated in FIG. 3, according to an embodiment. FIG. 10 is enlarged views respectively illustrating the first touch sensor TS1, the second touch sensor TS2, and the third touch sensor TS3 of FIG. 3. FIG. 11 is enlarged views respectively illustrating the first touch sensor TS1, the fourth touch sensor TS4, and the fifth touch sensor TS5 of FIG. 3.

Referring to FIGS. 3, 4, 10, and 11, the areas of the touch electrodes TCE of the touch sensors TS arranged in different rows may be different from each other, and the areas of the touch electrodes TCE of the touch sensors TS arranged in different columns in each row may be the same. An embodiment described with reference to FIGS. 10 and 11 is a modified embodiment of an embodiment described in FIGS. 3 to 6, and thus, a repeated description will be omitted and a difference will be mainly described.

In an embodiment, the areas of the touch electrodes TCE of the first touch sensor TS1, the second touch sensor TS2, and the third touch sensor TS3 arranged in the same row may be substantially the same.

The area of the driving electrode TE of the first touch sensor TS1 arranged in the a^{th} column Ca and the p^{th} row Rp and the area of the driving electrode TE of the second touch sensor TS2 located in the b^{th} column Cb and the p^{th} row Rp may be substantially the same. The area of the sensing electrode RE of the first touch sensor TS1 arranged in the a^{th} column Ca and the p^{th} row Rp and the area of the sensing electrode RE of the second touch sensor TS2 arranged in the b^{th} column Cb and the p^{th} row Rp may be substantially the same.

The area of the driving electrode TE of the second touch sensor TS2 arranged in the b^{th} column Cb and the p^{th} row Rp and the area of the driving electrode TE of the third touch sensor TS3 arranged in the c^{th} column Cc and the p^{th} row Rp may be substantially the same. The area of the sensing electrode RE of the second touch sensor TS2 arranged in the b^{th} column Cb and the p^{th} row Rp and the area of the sensing electrode RE of the third touch sensor TS3 arranged in the c^{th} column Cc and the p^{th} row Rp may be substantially the same.

In an embodiment, the area of the first dummy pattern DP1 of the first touch sensor TS1 may be substantially the same as the area of the first dummy pattern DP1 of the second touch sensor TS2. In a plan view, an interval G1b between the driving electrode TE and the sensing electrode RE of the first touch sensor TS1 may be substantially the same as an interval G2b between the driving electrode TE and the sensing electrode RE of the second touch sensor TS2.

The area of the first dummy pattern DP1 of the second touch sensor TS2 may be substantially the same as the area of the first dummy pattern DP1 of the third touch sensor TS3. In a plan view, the interval G2b between the driving electrode TE and the sensing electrode RE of the second touch sensor TS2 may be substantially the same as an interval G3b between the driving electrode TE and the sensing electrode RE of the third touch sensor TS3.

Although the first touch sensor TS1, the second touch sensor TS2, and the third touch sensor TS3 arranged in the p^{th} row Rp are described in FIG. 10, the disclosure is not limited thereto. For example, the touch sensors TS located in different columns in another row may have substantially the same area. The fourth touch sensor TS4 arranged in the a^{th} column Cb and the s^{th} row, a touch sensor arranged in the b^{th} column Cb and the s^{th} row Rs, and a touch sensor arranged in the c^{th} column Cc and the s^{th} row Rs may have substantially the same area.

In an embodiment, the area of the touch electrode TCE of the touch sensor TS arranged in a row in which the driving electrode line TEL having a relatively large length is located may be less than the area of the touch electrode TCE of the touch sensor TS arranged in a row in which the driving electrode line TEL having a relatively small length is located. In other words, the area of the touch electrode TCE of the touch sensor TS arranged in a row in which more touch sensors TS are located may be less than the area of the touch electrode TCE of the touch sensor TS arranged in a row in which fewer touch sensors TS are located.

As shown in FIG. 11, the area of the touch electrode TCE of the first touch sensor TS1 located in the p^{th} row Rp may be less than the area of the touch electrode TCE of the fourth touch sensor TS4 located in the s^{th} row Rs. The area of the driving electrode TE of the first touch sensor TS1 located in the p^{th} row Rp may be less than the area of the driving electrode TE of the fourth touch sensor TS4 located in the s^{th} row Rs. The area of the sensing electrode RE of the first touch sensor TS1 of the p^{th} row Rp may be less than the area of the sensing electrode RE of the fourth touch sensor TS4 located in the s^{th} row Rs.

The area of the touch electrode TCE of the fourth touch sensor TS4 located in the s^{th} row Rs may be less than the area of the touch electrode TCE of the fifth touch sensor TS5 located in the t^{th} row Rt. The area of the driving electrode TE of the fourth touch sensor TS4 located in the s^{th} row Rs may be less than the area of the driving electrode TE of the fifth touch sensor TS5 located in the t^{th} row Rt. The area of the sensing electrode RE of the fourth touch sensor TS4 located in the s^{th} row Rs may be less than the area of the sensing electrode RE of the fifth touch sensor TS5 located in the t^{th} row Rt.

The area of the first dummy pattern DP1 of the first touch sensor TS1 may be greater than the area of the first dummy pattern DP1 of the fourth touch sensor TS4. In a plan view, the interval G1b between the driving electrode TE and the sensing electrode RE of the first touch sensor TS1 may be greater than an interval G4b between the driving electrode TE and the sensing electrode RE of the fourth touch sensor TS4.

The area of the first dummy pattern DP1 of the fourth touch sensor TS4 may be greater than the area of the first dummy pattern DP1 of the fifth touch sensor TS5. In a plan view, the interval G4b between the driving electrode TE and the sensing electrode RE of the fourth touch sensor TS4 may be greater than an interval G5b between the driving electrode TE and the sensing electrode RE of the fifth touch sensor TS5.

In an embodiment of FIGS. 10 and 11, because the area of the touch electrode TCE arranged in a row in which more touch sensors TS are located (e.g., the p^{th} row Rp) is smaller than the area of the touch electrode TCE arranged in a row in which fewer touch sensors TS are located (e.g., the s^{th} row Rs), a difference in parasitic capacitance values may be reduced.

In an embodiment of FIGS. 10 and 11, although the areas of the touch electrodes TCE arranged in separate rows are different by making the areas of the first dummy patterns DP1 arranged in separate rows different from each other, the disclosure is not limited thereto. For example, in an embodiment of FIGS. 10 and 11, the touch sensor TS may further include the second dummy pattern DP2 and the areas of the touch electrodes TCE may become different using the second dummy patterns DP2, like an embodiment of FIGS. 7 to 9. For example, the area of the second dummy pattern DP2 of the touch sensor TS arranged in a row in which more touch sensors TS are located may be greater than the area of the second dummy pattern DP2 of the touch sensor TS arranged in a row in which fewer touch sensors TS are located.

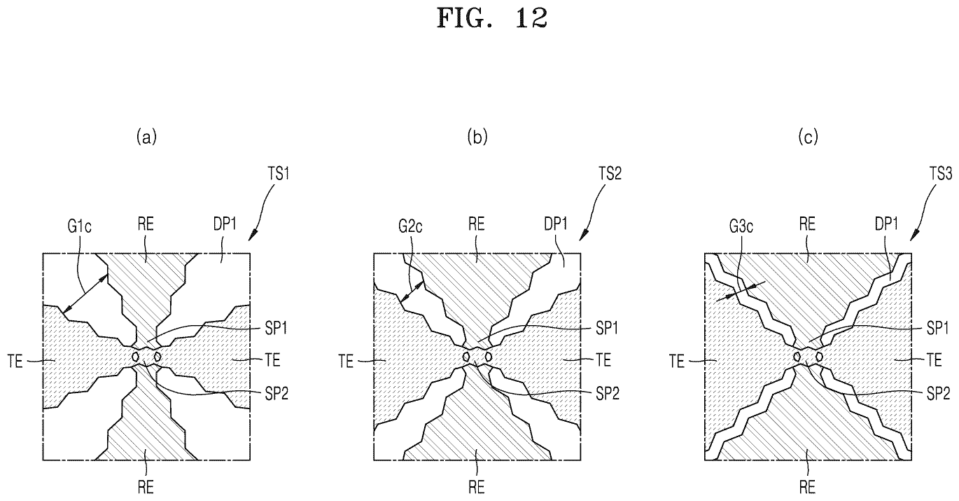

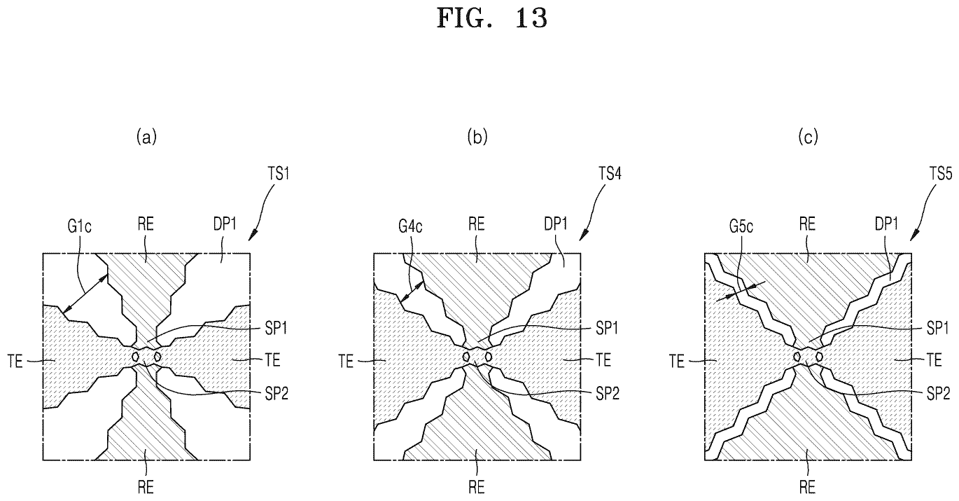

FIGS. 12 and 13 are enlarged views schematically illustrating touch sensors located at different positions illustrated in FIG. 3, according to an embodiment.

FIGS. 12 and 13 are enlarged views schematically illustrating touch sensors located at different positions illustrated in FIG. 3, according to an embodiment. FIG. 12 is enlarged views respectively illustrating the first touch sensor TS1, the second touch sensor TS2, and the third touch sensor TS3 of FIG. 3. FIG. 13 is enlarged views respectively illustrating the first touch sensor TS1, the fourth touch sensor TS4, and the fifth touch sensor TS5 of FIG. 3.

In an embodiment described with reference to FIGS. 12 and 13, the areas of the touch electrodes TCE of the touch sensors TS arranged in different columns may be different from each other, and the areas of the touch electrodes TCE of the touch sensors TS arranged in different rows in each column may be different from each other. An embodiment described with reference to FIGS. 12 and 13 is a modified embodiment of embodiments described above, and thus, a repeated description will be omitted and a difference will be mainly described.

Referring to FIGS. 3, 4, 12, and 13, the area of the touch electrode TCE of the touch sensor TS arranged in a column in which the sensing electrode line REL having a relatively large length is located may be less than the area of the touch electrode TCE of the touch sensor TS arranged in a column in which the sensing electrode line REL having a relatively small length is located. Also, the area of the touch electrode TCE of the touch sensor TS arranged in a row in which the driving electrode line TEL having a relatively large length is located may be less than the area of the touch electrode TCE of the touch sensor TS arranged in a row in which the driving electrode line TEL having a relatively small length is located. In an embodiment, when the touch active area SA has a circular shape as shown in FIG. 3, the area of the touch electrode TCE of the touch sensor TS may increase as the touch sensor TS gets away from the center of the touch active area SA.

In an embodiment, the area of the touch electrode TCE of the touch sensor TS located in a column in which more touch sensors TS are located may be less than the area of the touch electrode TCE of the touch sensor TS located in a column in which fewer touch sensors TS are located. Also, the area of the touch electrode TCE of the touch sensor TS located in a row in which more touch sensors TS are located may be less than the area of the touch electrode TCE of the touch sensor TS located in a row in which fewer touch sensors TS are located.

As shown in FIG. 12, the area of the touch electrode TCE of the first touch sensor TS1 arranged in the a^{th} column Ca may be less than the area of the touch electrode TCE of the second touch sensor TS2 arranged in the b^{th} column Cb. The area of the touch electrode TCE of the second touch sensor TS2 arranged in the b^{th} column Cb may be less than the area of the touch electrode TCE of the third touch sensor TS3 arranged in the c^{th} column Cc. Also, as shown in FIG. 13, the area of the touch electrode TCE of the first touch sensor TS1 arranged in the p^{th} row Rp may be less than the area of the touch electrode TCE of the fourth touch sensor TS4 arranged in the s^{th} row Rs. The area of the touch electrode TCE of the fourth touch sensor TS4 arranged in the s^{th} row RS may be less than the area of the touch electrode TCE of the fifth touch sensor TS5 arranged in the t^{th} row Rt.

In an embodiment, the area of the first dummy pattern DP1 of the first touch sensor TS1 may be greater than the area of the first dummy pattern DP1 of the second touch sensor TS2. The area of the first dummy pattern DP1 of the second touch sensor TS2 may be greater than the area of the first dummy pattern DP1 of the third touch sensor TS3. Also, as shown in FIG. 13, the area of the first dummy pattern DP1 of the first touch sensor TS1 may be greater than the area of the first dummy pattern DP1 of the fourth touch sensor TS4. The area of the first dummy pattern DP1 of the fourth touch sensor TS4 may be greater than the area of the first dummy pattern DP1 of the fifth touch sensor TS5.

As shown in FIG. 12, in a plan view, an interval G1c between the driving electrode TE and the sensing electrode RE of the first touch sensor TS1 may be greater than an interval G2c between the driving electrode TE and the sensing electrode RE of the second touch sensor TS2. The interval G2c between the driving electrode TE and the sensing electrode RE of the second touch sensor TS2 may be greater than an interval G3c between the driving electrode TE and the sensing electrode RE of the third touch sensor TS3. Also, as shown in FIG. 13, in a plan view, the interval G1c between the driving electrode TE and the sensing electrode RE of the first touch sensor TS1 may be greater than an interval G4c between the driving electrode TE and the sensing electrode RE of the fourth touch sensor TS4. The interval G4c between the driving electrode TE and the sensing electrode RE of the fourth touch sensor TS4 may be greater than an interval G5c between the driving electrode TE and the sensing electrode RE of the fifth touch sensor TS5.

In an embodiment of FIGS. 12 and 13, because the area of the touch electrode TCE in a column in which more touch sensors TS are located (e.g., the a^{th} column Ca) is smaller than the area of the touch electrode TCE in a column in which fewer touch sensors TS are located (e.g., the b^{th} column Cb), and the area of the touch electrode TCE in a row in which more touch sensors TS are located (e.g., the p^{th} row Rp) is smaller than the area of the touch electrode TCE in a row in which fewer touch sensors TS are located (e.g., the s^{th} row Rs), a difference in parasitic capacitance values may be reduced.

In an embodiment of FIGS. 12 and 13, although the areas of the touch electrodes TCE arranged in separate rows and columns are different by making the areas of the first dummy patterns DP1 arranged in separate rows and columns different from each other, the disclosure is not limited thereto. For example, in an embodiment of FIGS. 12 and 13, the touch sensor TS may further include the second dummy pattern DP2 and the areas of the touch electrodes TCE may be different using the second dummy patterns DP2 having different areas.

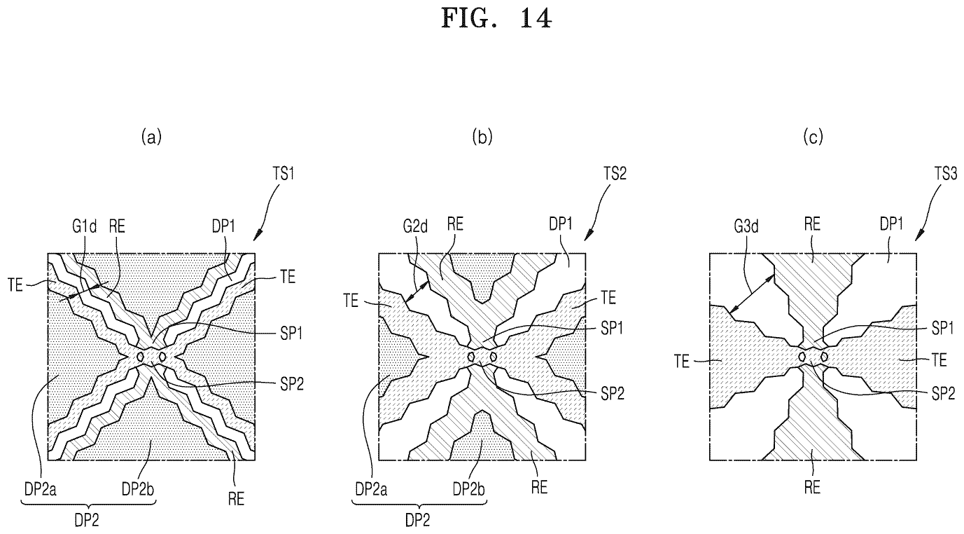

FIG. 14 is an enlarged view schematically illustrating touch sensors located at different positions illustrated in FIG. 3, according to an embodiment. FIG. 14 is enlarged views respectively illustrating the first touch sensor TS1, the second touch sensor TS2, and the third touch sensor TS3 of FIG. 3.

An embodiment described with reference to FIG. 14 is a modified embodiment of an embodiment described in FIGS. 3 to 6, and thus, a detailed description will be omitted and a difference will be mainly described.

Referring to FIG. 14, the area of the touch electrode TCE of the touch sensor TS arranged in a column in which more touch sensors TS are located may be less than the area of the touch electrode TCE of the touch sensor TS arranged in a column in which fewer touch sensors TS are located. Also, an interval between the driving electrode TE and the sensing electrode RE of the touch sensor TS arranged in a column in which more touch sensors TS are located may be less than an interval between the driving electrode TE and the sensing electrode RE of the touch sensor TS arranged in a column in which fewer touch sensors TS are located.

Because an interval between the driving electrode TE and the sensing electrode RE is relatively small in the touch sensor TS in which the area of the touch electrode TCE is small, even when the area of the touch electrode TCE gets slightly reduced, the amount of change in mutual capacitance between the driving electrode TE and the sensing electrode RE of the touch sensor TS may be smoothly measured.

In an embodiment, the area of the first dummy pattern DP1 of the touch sensor TS arranged in a column in which the sensing electrode line REL having a relatively large length is located may be less than the area of the first dummy pattern DP1 of the touch sensor TS arranged in a column in which the sensing electrode line REL having a relatively small length is located. In other words, the area of the first dummy pattern DP1 of the touch sensor TS arranged in a column in which more touch sensors TS are located may be less than the area of the first dummy pattern DP1 of the touch sensor TS arranged in a column in which fewer touch sensors TS are located. In an embodiment, an interval between the driving electrode TE and the sensing electrode RE of the touch sensor TS arranged in a column in which more touch sensors TS are located may be less than an interval between the driving electrode TE and the sensing electrode RE of the touch sensor TS arranged in a column in which fewer touch sensors TS are located.

The area of the first dummy pattern DP1 of the first touch sensor TS1 may be less than the area of the first dummy pattern DP1 of the second touch sensor TS2. In an embodiment, in a plan view, an interval G1d between the driving electrode TE and the sensing electrode RE of the first touch sensor TS1 may be less than an interval G2d between the driving electrode TE and the sensing electrode RE of the second touch sensor TS2.

The area of the first dummy pattern DP1 of the second touch sensor TS2 may be less than the area of the first dummy pattern DP1 of the third touch sensor TS3. In a plan view, the interval G2d between the driving electrode TE and the sensing electrode RE of the second touch sensor TS2 may be less than an interval G3d between the driving electrode TE and the sensing electrode RE of the third touch sensor TS3.

In an embodiment, at least some of the touch sensors TS may include the second dummy pattern DP2 located inside the touch electrode TCE. In an embodiment, some of the touch sensors TS may include the second dummy pattern DP2 inside the touch electrode TCE, and some others may not include the second dummy pattern DP2 inside the touch electrode TCE. That is, while some of the touch sensors TS may include the driving electrode TE and the sensing electrode RE each of which is formed in a ring shape, some others may include the driving electrode TE and the sensing electrode RE each of which has a non-ring shape.

In an embodiment, the area of the second dummy pattern DP2 of the touch sensor TS arranged in a column in which the sensing electrode line REL having a relatively large length is located may be greater than the area of the second dummy pattern DP2 of the touch sensor TS arranged in a column in which the sensing electrode line REL having a relatively small length is located. In other words, the area of the second dummy pattern DP2 of the touch sensor TS arranged in a column in which more touch sensors TS are located may be greater than the area of the second dummy pattern DP2 of the touch sensor TS arranged in a column in which fewer touch sensors TS are located. Accordingly, the area of the touch electrode TCE of the touch sensor TS located in a column in which more touch sensors TS are located may be less than the area of the touch electrode TCE of the touch sensor TS located in a column in which fewer touch sensors TS are located.

The area of the second dummy pattern DP2 of the first touch sensor TS1 arranged in the a^{th} column Ca may be greater than the area of the second dummy pattern DP2 of the second touch sensor TS2 arranged in the b^{th} column Cb. The area of the 2-1 dummy pattern DP2a of the first touch sensor TS1 may be greater than the area of the 2-1 dummy pattern DP2a of the second touch sensor TS2. The area of the 2-2 dummy pattern DP2b of the first touch sensor TS1 may be greater than the area of the 2-2 dummy pattern DP2b of the second touch sensor TS2.

In an embodiment, the touch sensor TS arranged in a column in which the sensing electrode line REL having a relatively large length is located may include the second dummy pattern DP2, and the touch sensor TS arranged in a column in which the sensing electrode line REL having a relatively small length is located may not include the second dummy pattern DP2. In other words, the touch sensor TS located in a column in which more touch sensors TS are located may include the second dummy pattern DP2, and the touch sensor TS located in a column in which fewer touch sensors TS are located may not include the second dummy pattern DP2. For example, the third touch sensor TS3 arranged in the c^{th} column Cc may not include the second dummy pattern DP2. That is, the third touch sensor TS3 may have a non-ring shape. Even when the interval G3d between the driving electrode TE and the sensing electrode RE is relatively large, the third touch sensor TS3 does not include the second dummy pattern DP2, and thus, the area of the touch electrode TCE may be relatively large.

In an embodiment, as described with reference to FIGS. 5 and 6, the areas or shapes of the touch electrodes TCE of the touch sensors TS arranged in different rows in each column (e.g., the first touch sensor TS1, the fourth touch sensor TS4, and the fifth touch sensor TS5) may be the same.

Also, in an embodiment, as described with reference to FIGS. 12 and 13, the areas of the touch electrodes TCE of the touch sensors TS arranged in different rows in each column (e.g., the first touch sensor TS1, the fourth touch sensor TS4, and the fifth touch sensor TS5) may be different from each other. For example, an interval between the driving electrode DE and the sensing electrode RE of the first touch sensor TS1 may be less than an interval between the driving electrode TE and the sensing electrode RE of the fourth touch sensor TS4, and the area of the second dummy pattern DP2 of the first touch sensor TS1 may be greater than the area of the dummy pattern DP2 of the fourth touch sensor TS4. For example, an interval between the driving electrode TE and the sensing electrode RE of the fourth touch sensor TS4 may be less than an interval between the driving electrode TE and the sensing electrode RE of the fifth touch sensor TS5, and the fifth touch sensor TS5 may not include the second dummy pattern DP2.

In an embodiment, although the areas and shapes of the touch sensors TS arranged in different columns are described, the present disclosure is not limited thereto. For example, as described in FIGS. 10 and 11, an embodiment illustrated in FIG. 14 may be modified such that the areas and shapes of the touch electrodes TCE of the touch sensors TS arranged in different rows in each column may be different.

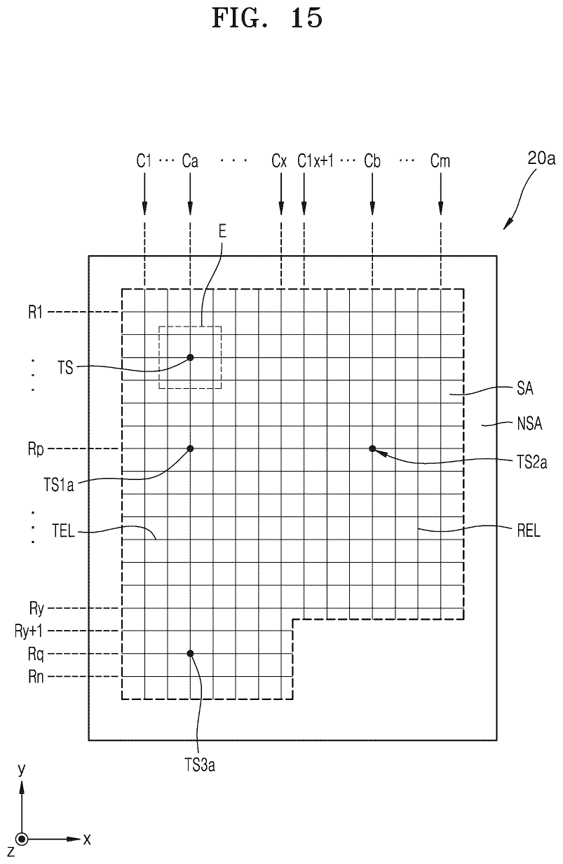

FIG. 15 is a plan view schematically illustrating a touch sensing unit 20a included in the display apparatus 1.

In FIG. 15, as the display area DA of the display apparatus 1 has an irregular shape, the touch sensing unit 20a includes the touch active area SA having an irregular shape. FIG. 15 is a modified embodiment of FIG. 3, and thus, a repeated description will be omitted and a difference will be mainly described.

A portion ‘E’ of FIG. 15 may have the same configuration as depicted in FIG. 4. However, the present embodiment is not limited thereto, and an enlarged view of the portion ‘E’ of FIG. 15 may be FIG. 7. That is, at least some of the touch sensors TS may include the second dummy pattern DP2. For convenience of explanation, the following will be described assuming that an embodiment does not include the second dummy pattern DP2.

Although not shown in FIG. 15, the touch sensing unit 20a may further include the pad area PADA disposed in the touch inactive area NSA.

Referring to FIG. 15, the driving electrode lines TEL may extend respectively along a first row R1 to an n^{th} row Rn, and the sensing electrode lines REL may extend respectively along a first column C1 to an m^{th} column Cm (each of n and m is a natural numbers equal to or greater than 3).

The driving electrode lines TEL may include at least two driving electrode lines TEL having different lengths. In an embodiment, as shown in FIG. 15, the touch active area SA may include the driving electrode lines TEL having a first length in the first row R1 to a y^{th} row Ry, and may include the driving electrode lines TEL having a second length in a y+1^{th} row Ry+1 to the n^{th} row Rn (y is a natural number equal to or less than n). In an embodiment, the first length of the driving electrode lines TEL disposed in the first row R1 to the y^{th} row Ry may be greater than the second length of the driving electrode lines TEL disposed in the y+1^{th} row Ry+1 to the n^{th} row Rn.

In an embodiment, the number of touch sensors TS disposed in one of the first row R1 to the y^{th} row Ry may be greater than the number of touch sensors TS disposed in one of the y+1^{th} row Ry+1 to the n^{th} row Rn. For example, the number of touch sensors TS located in a p^{th} row Rp may be greater than the number of touch sensors TS located in a q^{th} row Rq (p is a natural number equal to or less than y, and q is a natural number ranging from y+1 to n).

The sensing electrode lines REL may include at least two sensing electrode lines REL having different lengths. In an embodiment, as shown in FIG. 15, the touch active area SA may include the sensing electrode lines REL having a third length in the first column C1 to an x^{th} column Cx, and may include the sensing electrode lines REL having a fourth length in an x+1^{th} column Cx+1 to the m^{th} column Cm (x is a natural number equal to or less than m). In an embodiment, the third length of the sensing electrode lines REL disposed in the first column C1 to the x^{th} column Cx may be greater than the fourth length of the sensing electrode lines REL disposed in the x+1^{th} column Cx+1 to the m^{th} column Cm.

In an embodiment, the number of touch sensors TS disposed in one of the first column C1 to the x^{th} column Cx may be greater than the number of touch sensors TS disposed in one of the x+1^{th} column Cx+1 to the m^{th} column Cm. For example, the number of touch sensors TS located in an a^{th} column Ca may be greater than the number of touch sensors TS located in a b^{th} column Cb (a is a natural number equal to or less than x, and b is a natural number ranging from x+1 to m).

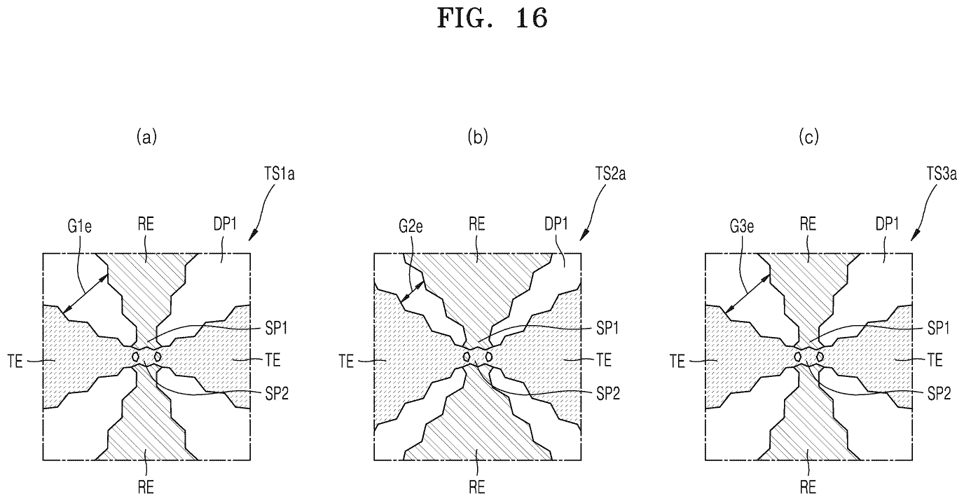

FIG. 16 is an enlarged view schematically illustrating touch sensors located at different positions illustrated in FIG. 15.

FIG. 16 is enlarged views respectively illustrating a first touch sensor TS1a, a second touch sensor TS2a, and a third touch sensor TS3a of FIG. 15, according to an embodiment.

The first touch sensor TS1a and the second touch sensor TS2a are arranged in the same row but are disposed in different columns. In detail, the first touch sensor TS1a may be positioned at an intersection between the a^{th} column Ca and the p^{th} row Rp, and the second touch sensor TS2a may be positioned at an intersection between the b^{th} column Cb and the p^{th} row Rp (a is a natural number equal to or less than x, and b is a natural number ranging from x+1 to m).

The first touch sensor TS1a and the third touch sensor TS3a are arranged in the same column but are disposed in different rows. In detail, the third touch sensor TS3a may be positioned at an intersection between the a^{th} column Ca and the q^{th} row Rq (p is a natural number equal to or less than y, and q is a natural number ranging from y+1 to n).

Referring to FIGS. 4, 15, and 16, the areas of the touch electrodes TCE of the touch sensors TS arranged in different columns may be different from each other, and the areas of the touch electrodes TCE of the touch sensors TS arranged in different rows may be the same.

In an embodiment, the area of the touch electrode TCE of the touch sensor TS arranged in a column in which the sensing electrode line REL having a relatively large length is located (e.g., one of the first column C1 to the x^{th} column Cx) may be less than the area of the touch electrode TCE of the touch sensor TS arranged in a column in which the sensing electrode line REL having a relatively small length is located (e.g., one of the x+1^{th} column Cx+1 to the m^{th} column Cm). In other words, the area of the touch electrode TCE of the touch sensor TS located in a column in which more touch sensors TS are located (e.g., one of the first column C1 to the x^{th} column Cx) may be less than the area of the touch electrode TCE of the touch sensor TS located in a column in which fewer touch sensors TS are located (e.g., one of the x+1^{th} column Cx+1 to the m^{th} column Cm).

The area of the touch electrode TCE of the first touch sensor TS1a positioned in the a^{th} column Ca may be less than the area of the touch electrode TCE of the second touch sensor TS2a positioned in the b^{th} column Cb. The area of the driving electrode TE of the first touch sensor TS1a positioned in the a^{th} column Ca may be less than the area of the driving electrode TE of the second touch sensor TS2a positioned in the b^{th} column Cb. The area of the sensing electrode RE of the first touch sensor TS1a positioned in the a^{th} column Ca may be less than the area of the sensing electrode RE of the second touch sensor TS2a positioned in the b^{th} column Cb.

In an embodiment, the area of the first dummy pattern DP1 of the touch sensor TS arranged in a column in which the sensing electrode line REL having a relatively large length is located may be greater than the area of the first dummy pattern DP1 of the touch sensor TS arranged in a column in which the sensing electrode line REL having a relatively small length is located. In other words, the area of the first dummy pattern DP1 of the touch sensor TS disposed in a column in which more touch sensors TS are located may be greater than the area of the first dummy pattern DP1 of the touch sensor TS disposed in a column in which fewer touch sensors TS are located. In an embodiment, an interval between the driving electrode TE and the sensing electrode RE of the touch sensor TS located in a column in which more touch sensors TS are located may be greater than an interval between the driving electrode TE and the sensing electrode RE of the touch sensor TS in which fewer touch sensors TS are located.

The area of the first dummy pattern DP1 of the first touch sensor TS1a may be greater than the area of the first dummy pattern DP1 of the second touch sensor TS2a. In an embodiment, in a plan view, an interval G1e between the driving electrode TE and the sensing electrode RE of the first touch sensor TS1a may be greater than an interval G2e between the driving electrode TE and the sensing electrode RE of the second touch sensor TS2a.

In an embodiment, the areas of the touch sensors TS arranged in different rows in each column may be substantially the same. The area of the touch electrode TCE of the first touch sensor TS1a and the area of the touch electrode TCE of the third touch sensor TS3a arranged in the same column may be substantially the same.

The area of the driving electrode TE of the first touch sensor TS1a located in the a^{th} column Ca and the p^{th} row Rp and the area of the driving electrode TE of the third touch sensor TS3a located in the a^{th} column Ca and the q^{th} row Rq may be substantially the same. The area of the sensing electrode RE of the first touch sensor TS1a located in the a^{th} column Ca and the p^{th} row Rp and the area of the sensing electrode RE of the third touch sensor TS3a located in the a^{th} column Ca and the q^{th} row Rq may be substantially the same.

The area of the first dummy pattern DP1 of the first touch sensor TS1a may be substantially the same as the area of the first dummy pattern DP1 of the third touch sensor TS3a. In a plan view, the interval G1e between the driving electrode TE and the sensing electrode RE of the first touch sensor TS1a may be substantially the same as an interval G3e between the driving electrode TE and the sensing electrode RE of the third touch sensor TS3a.

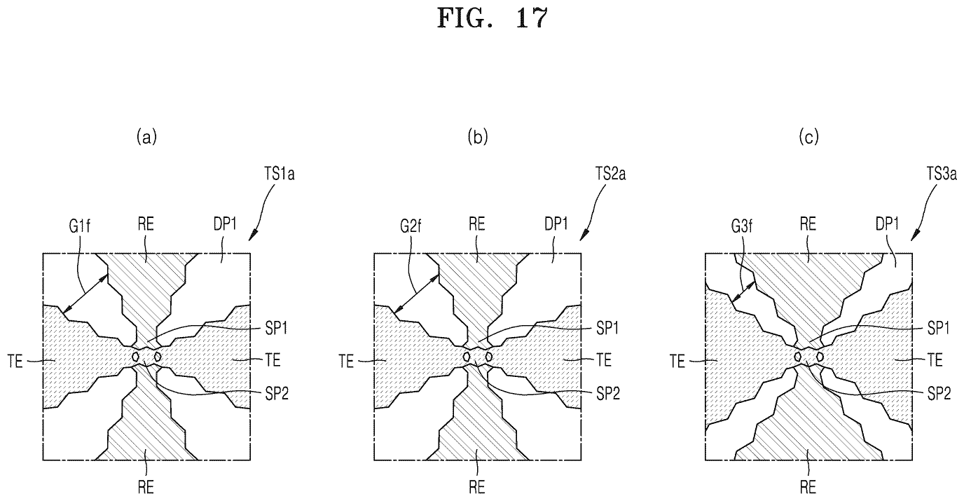

FIG. 17 is an enlarged view schematically illustrating touch sensors located at different positions illustrated in FIG. 15, according to an embodiment.

Referring to FIGS. 4, 15, and 17, the areas of the touch electrodes TCE of the touch sensors TS arranged in different rows may be different from each other, and the areas of the touch electrodes TCE of the touch sensors TS arranged in different columns may be the same.

In an embodiment, the area of the touch electrode TCE of the touch sensor TS arranged in a row in which the driving electrode line TEL having a relatively large length is located (e.g., one of the first row R1 to the y^{th} row Ry) may be less than the area of the touch electrode TCE of the touch sensor TS arranged in a row in which the driving electrode line TEL having a relatively small length is located (e.g., one of the y+1^{th} row Ry+1 to the n^{th} row Rn). In other words, the area of the touch electrode TCE of the touch sensor TS located in a row in which more touch sensors TS are located (e.g., one of the first row R1 to the y^{th} row Ry) may be less than the area of the touch electrode TCE of the touch sensor TS located in a row in which fewer touch sensors TS are located (e.g., one of the y+1^{th} row Ry+1 to the n^{th} row Rn).

The area of the touch electrode TCE of the first touch sensor TS1a arranged in the p^{th} row Rp may be less than the area of the touch electrode TCE of the third touch sensor TS3a arranged in the q^{th} row Rq. The area of the driving electrode TE of the first touch sensor TS1a located in the p^{th} row Rp may be less than the area of the driving electrode TE of the third touch sensor TS3a located in the q^{th} row Rq. The area of the sensing electrode RE of the first touch sensor TS1a located in the p^{th} row Rp may be less than the area of the sensing electrode RE of the third touch sensor TS3a located in the q^{th} row Rq.

In an embodiment, the area of the first dummy pattern DP1 of the touch sensor TS arranged in a row in which the driving electrode line TEL having a relatively large length is located may be greater than the area of the first dummy pattern DP1 of the touch sensor TS arranged in a row in which the driving electrode line TEL having a relatively small length is located. In the words, the area of the first dummy pattern DP1 of the touch sensor TS located in a row in which more touch sensors TS are located may be greater than the area of the first dummy pattern DP1 of the touch sensor TS located in a row in which fewer touch sensors TS are located. In an embodiment, an interval between the driving electrode TE and the sensing electrode RE of the touch sensor TS arranged in a row in which more touch sensors TS are located may be greater than an interval between the driving electrode TE and the sensing electrode RE of the touch sensor TS arranged in a row in which fewer touch sensors TS are located.

The area of the first dummy pattern DP1 of the first touch sensor TS1a may be greater than the area of the first dummy pattern DP1 of the third touch sensor TS3a. In an embodiment, in a plan view, the interval G1e between the driving electrode TE and the sensing electrode RE of the first touch sensor TS1a may be greater than the interval G3e between the driving electrode TE and the sensing electrode RE of the third touch sensor TS3a.

In an embodiment, the areas of the touch sensors TS arranged in different columns in each row may be substantially the same. The area of the touch electrode TCE of the first touch sensor TS1a and the area of the touch electrode TCE of the second touch sensor TS2a arranged in the same row may be substantially the same.

The area of the driving electrode TE of the first touch sensor TS1a located in the a^{th} column Ca and the p^{th} row Rp and the area of the driving electrode TE of the second touch sensor TS2a located in the b^{th} column Cb and the p^{th} row Rp may be substantially the same. The area of the sensing electrode RE of the first touch sensor TS1a located in the a^{th} column Ca and the p^{th} row Rp and the area of the sensing electrode RE of the second touch sensor TS2a located in the b^{th} column Cb and the p^{th} row Rp may be substantially the same.

The area of the first dummy pattern DP1 of the first touch sensor TS1a may be substantially the same as the area of the first dummy pattern DP1 of the second touch sensor TS2a. In a plan view, the interval G1e between the driving electrode TE and the sensing electrode RE of the first touch sensor TS1a may be substantially the same as the interval G2e between the driving electrode TE and the sensing electrode RE of the second touch sensor TS2a.

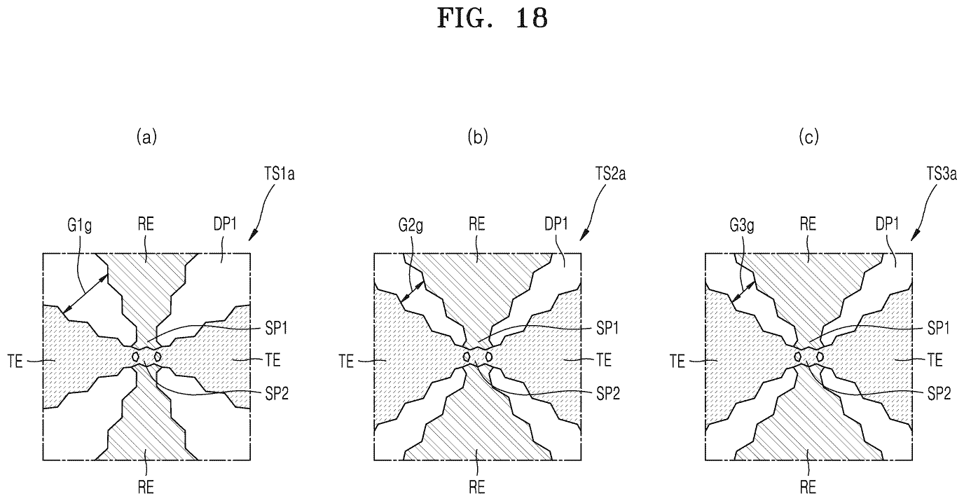

FIG. 18 is an enlarged view schematically illustrating touch sensors located at different positions illustrated in FIG. 15, according to an embodiment.

Referring to FIGS. 4, 15, and 18, the areas of the touch electrodes TCE of the touch sensors TS arranged in different columns may be different from each other, and the areas of the touch electrodes TCE of the touch sensors TS arranged in different rows may be different from each other.

In an embodiment, the area of the touch electrode TCE of the touch sensor TS arranged in a column in which more touch sensors TS are located (e.g., one of the first column C1 to the x^{th} column Cx) may be less than the area of the touch electrode TCE of the touch sensor TS arranged in a column in which fewer touch sensors TS are located (e.g., one of the x+1^{th} column Cx+1 to the m^{th} column Cm). Also, the area of the touch electrode TCE of the touch sensor TS arranged in a row in which more touch sensors TS are located (e.g., one of the first row R1 to the y^{th} row Ry) may be less than the area of the touch electrode TCE of the touch sensor TS arranged in a row in which fewer touch sensors TS are located (e.g., one of the y+1^{th} row Ry+1 to the n^{th} row Rn).

That is, the area of the touch electrode TCE of the touch sensor TS positioned at an intersection between a column in which more touch sensors TS are located (e.g., one of the first column C1 to the x^{th} column Cx) and a row in which more touch sensors TS are located (e.g., one of the first row R1 to the y^{th} row Ry) may be less than the area of the touch electrode TCE of the touch sensor TS positioned in the remaining region.

For example, the area of the touch electrode TCE of the first touch sensor TS1a positioned at an intersection between the a^{th} column, which is one of the first column C1 to the x^{th} column Cx, and the p^{th} row, which is one of the first row R1 to the y^{th} row Ry, may be less than the area of the touch electrode TCE of the second touch sensor TS2a positioned at an intersection between the b^{th} column, which is one of the x+1^{th} column Cx+1 to the m^{th} column Cm, and the p^{th} row. The area of the driving electrode TE of the first touch sensor TS1a may be less than the area of the driving electrode TE of the second touch sensor TS2a. The area of the sensing electrode RE of the first touch sensor TS1a may be less than the area of the sensing electrode RE of the second touch sensor TS2a.

For example, the area of the touch electrode TCE of the first touch sensor TS1a positioned at an intersection between the a^{th} column, which is one of the first column C1 to the x^{th} column Cx, and the p^{th} row, which is one of the first row R1 to the y^{th} row Ry, may be less than the area of the touch electrode TCE of the third touch sensor TS3a positioned at an intersection between the a^{th} column and the q^{th} row, which is one of the y+1^{th} row Ry+1 to the n^{th} row Rn. The area of the driving electrode TE of the first touch sensor TS1a may be less than the area of the driving electrode TE of the third touch sensor TS3a. The area of the sensing electrode RE of the first touch sensor TS1a may be less than the area of the sensing electrode RE of the third touch sensor TS3a.

The area of the first dummy pattern DP1 of the first touch sensor TS1a may be greater than the area of the first dummy pattern DP1 of each of the second touch sensor TS2a and the third touch sensor TS3a. An interval G1f between the driving electrode TE and the sensing electrode RE of the first touch sensor TS1a may be greater than an interval G2f between the driving electrode TE and the sensing electrode RE of the second touch sensor TS2a and an interval G3f between the driving electrode TE and the sensing electrode RE of the third touch sensor TS3a.

In embodiments described with reference to FIGS. 15 to 18, although the areas of the touch electrodes TCE arranged in separate rows or columns are different by making the areas of the first dummy patterns DP1 arranged in separate rows or columns different from each other, the disclosure is not limited thereto. For example, in embodiments described with reference to FIGS. 15 to 18, the touch sensor TS may further include the second dummy pattern DP2 and the areas of the touch electrodes TCE may become different using the second dummy patterns DP2, like an embodiment as illustrated in FIGS. 7 to 9. For example, in embodiments of FIGS. 15 to 18, the areas of the touch electrodes TCE may be different by further including the second dummy patterns DP2 having different area.

FIG. 19 is a cross-sectional view schematically illustrating the display apparatus 1, according to an embodiment. FIG. 19 is a view schematically illustrating a stacked structure of the display panel 10 and the touch sensing unit 20.

Referring to FIG. 19, the display panel 10 may include the substrate 100, a pixel circuit layer disposed on the substrate 100 and including a pixel circuit PC, an organic light-emitting diode OLED disposed on the pixel circuit layer, and the encapsulation layer 300 on the organic light-emitting diode OLED.

The pixel circuit layer may include the pixel circuit PC including the thin-film transistor TFT and the storage capacitor Cst, and insulating layers IL. The plurality of insulating layers IL may include a barrier layer 101, a buffer layer 102, a first gate insulating layer 103, a second gate insulating layer 104, an interlayer insulating layer 105, and a planarization insulating layer 107.

The buffer layer 102 may be disposed on the substrate 100 to reduce or block penetration of a foreign material, moisture, or external air from the bottom of the substrate 100 and to planarize a semiconductor layer Act. The buffer layer 102 may include an inorganic material such as oxide or nitride, an organic material, or an organic/inorganic composite material, and may have a single or multi-layer structure including an inorganic material and an organic material.

The barrier layer 101 may be further provided between the substrate 100 and the buffer layer 102 to prevent the penetration of external air. The barrier layer 101 and the buffer layer 102 may include silicon oxide (SiO₂) or silicon nitride (SiN_{X}).

The pixel circuit PC including the thin-film transistor TFT and the storage capacitor Cst may be disposed on the buffer layer 102. The thin-film transistor TFT may include the semiconductor layer Act, a gate electrode GE, a drain electrode DE, and a source electrode SE.

The semiconductor layer Act may be disposed on the buffer layer 102 and may include polysilicon, amorphous silicon, or an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer Act may include a channel region, and a source region and a drain region doped with impurities. The source region and the drain region may be formed on two opposite sides of the channel region.

The first gate insulating layer 103 may be provided to cover the semiconductor layer Act. The first gate insulating layer 103 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first gate insulating layer 103 may have a single or multi-layer structure including the inorganic insulating material.

The gate electrode GE may be disposed on the first gate insulating layer 103 and overlap the semiconductor layer Act. The gate electrode GE may include molybdenum (Mo), aluminum (Al), copper (Cu), or titanium (Ti), and may have a single or multi-layer structure. For example, the gate electrode GE may have a single-layer structure including Mo.

The second gate insulating layer 104 may be provided to cover the gate electrode GE. The second gate insulating layer 104 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The second gate insulating layer 104 may have a single or multi-layer structure including the inorganic insulating material.

A second capacitor electrode CE2 of the storage capacitor Cst may be disposed on the second gate insulating layer 104. The second capacitor electrode CE2 may overlap the gate electrode GE. The gate electrode GE and the second capacitor electrode CE2 may overlap with each other, and the second gate insulating layer 104 is interposed therebetween to constitute the storage capacitor Cst. That is, the gate electrode GE may function as a first capacitor electrode CE1 of the storage capacitor Cst.

The second capacitor electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may have a single or multi-layer structure including the above material.

The interlayer insulating layer 105 may be formed to cover the second capacitor electrode CE2. The interlayer insulating layer 105 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 15 may have a single or multi-layer structure including the inorganic insulating material.

The source electrode SE and the drain electrode DE may be disposed on the interlayer insulating layer 105. Each of the source electrode SE and the drain electrode DE may include a conductive material including molybdenum (Mo), aluminum (Al), copper (Cu), or titanium (Ti), and may have a single or multi-layer structure including the above material. In an embodiment, each of the source electrode SE and the drain electrode DE may have a multi-layer structure including Ti/Al/Ti. In some embodiments, the source electrode SE or the drain electrode DE may be omitted. For example, adjacent thin-film transistors TFT may share the source region or the drain region of the semiconductor layer Act, and the source region or the drain region may function as the source electrode SE or the drain electrode DE.

The planarization insulating layer 107 may be disposed to cover the source electrode SE and the drain electrode DE. The planarization insulating layer 107 may provide a flat base surface for a pixel electrode 210 which is disposed on the first planarization insulating layer 107.

The planarization insulating layer 107 may include an organic material or an inorganic material, and may have a single or multi-layer structure. The planarization insulating layer 107 may include benzocyclobutene (BCB), polyimide, hexamethyldisiloxane (HMDSO), a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, or a vinyl alcohol-based polymer. The planarization insulating layer 107 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO₂). After forming the planarization insulating layer 107, chemical mechanical polishing may be performed on a top surface of the planarization insulating layer in order to provide a flat top surface.

The organic light-emitting diode OLED may be positioned on the planarization insulating layer 107. The organic light-emitting diode OLED may include the pixel electrode 210, an intermediate layer 220, and a counter electrode 230.

The pixel electrode 210 may be disposed on the planarization insulating layer 107. The planarization insulating layer 107 may include a via hole which extends to any one of the source electrode SE and the drain electrode DE of the thin-film transistor TFT, and the pixel electrode 210 may contact the source electrode SE or the drain electrode DE through the via hole and may be electrically connected to the thin-film transistor TFT.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 210 may have a structure having films formed of ITO, IZO, ZnO, or In₂O₃ over/under the reflective film. In an embodiment, the pixel electrode 210 may have a stacked structure including ITO/Ag/ITO.

A pixel-defining film 109 may be disposed on the planarization insulating layer 107 and cover an edge of the pixel electrode 210, and may include a pixel opening OP which extends to a central portion of the pixel electrode 210. A size and a shape of an emission area EA of the organic light-emitting diode OLED, that is, a pixel, may be defined by the pixel opening OP.

The pixel-defining film 109 may increase a distance between an edge of the pixel electrode 210 and the counter electrode 230 to prevent an arc or the like from occurring on the edge of the pixel electrode 210.

The pixel-defining film 109 may be formed of an organic insulating material such as polyimide, polyamide, acrylic resin, benzocyclobutene, hexamethyldisiloxane (HMDSO), or phenolic resin, by using spin coating or the like.

In an embodiment, the pixel-defining film 109 may further include a light-blocking material. The light-blocking material may include carbon black, carbon nanotubes, a resin or paste including a black dye, metal particles (e.g., nickel (Ni), aluminum (Al), molybdenum (Mo), or an alloy thereof), metal oxide particles (e.g., chromium oxide), or metal nitride particles (e.g., chromium nitride). When the pixel-defining film 109 includes a light-blocking material, the reflection of external light due to metal structures disposed under the pixel-defining film 109 may be reduced.

The intermediate layer 220 may be disposed between the pixel electrode 210 and the counter electrode 230. The intermediate layer 220 may include a first functional layer 221, an emission layer 222, and a second functional layer 223.

The emission layer 222 is disposed in the pixel opening OP of the pixel-defining film 109 to correspond to the pixel electrode 210. The emission layer 222 may include a high molecular weight material or a low molecular weight material, and may emit red light, green light, blue light, or white light.

The first functional layer 221 and the second functional layer 223 may be disposed on two opposite sides of the emission layer 222. In an embodiment, unlike the emission layer 222 being patterned and disposed in each pixel, the first functional layer 221 and the second functional layer 223 may be disposed over the entire display area DA.

The first functional layer 221 may have a single or multi-layer structure. For example, when the first functional layer 221 is formed of a high molecular weight material, the first functional layer 221 may include a hole transport layer having a single-layer structure, and may be formed of poly-(3,4)-ethylene-dihydroxythiophene (PEDOT) or polyaniline (PANI). When the first functional layer 221 is formed of a low molecular weight material, the first functional layer 221 may include a hole injection layer and a hole transport layer.

The second functional layer 223 may be selectively disposed. For example, when each of the first functional layer 221 and the emission layer 222 is formed of a high molecular weight material, the second functional layer 223 may be formed on the emission layer 222. The second functional layer 223 may have a single or multi-layer structure. The second functional layer 223 may include an electron transport layer or an electron injection layer. In some embodiments, at least one of the hole injection layer, the hole transport layer, the electron transport layer, and the electron injection layer may be omitted.

The counter electrode 230 may be formed of a conductive material having a relatively low work function. For example, the counter electrode 230 may include a (semi-)transparent layer including silver (Ag), magnesium (Mg), aluminum (Al), nickel (Ni), chromium (Cr), lithium (Li), calcium (Ca), or an alloy thereof. The counter electrode 230 may further include a layer formed of ITO, IZO, ZnO, or In₂O₃ on the (semi-)transparent layer including the above material. In an embodiment, the counter electrode 230 may include silver (Ag) and magnesium (Mg).

In an embodiment, a capping layer (not shown) may be disposed on the organic light-emitting diode OLED. The capping layer may improve the luminous efficiency of the light-emitting diode OLED. The capping layer may be an organic capping layer including an organic material, an inorganic capping layer including an inorganic material, or a composite including an organic material and an inorganic material.

The encapsulation member 300 may be disposed on the organic light-emitting diode OLED. In an embodiment, the encapsulation member 300 may include at least one inorganic encapsulation layer and at least one organic encapsulation layer. The encapsulation member 300 may include the first and second inorganic encapsulation layers 310 and 330, and the organic encapsulation layer 320 disposed between the first and second inorganic encapsulation layers 310 and 330.

Each of the first and second inorganic encapsulation layers 310 and 330 may include at least one inorganic insulating material. The inorganic insulating material may include aluminum oxide (Al₂O₃), titanium oxide (TiO₂), tantalum oxide (Ta₂O₅), hafnium oxide (HfO₂), zinc oxide (ZnO), silicon oxide (SiO₂), silicon nitride (SiNₓ), or silicon oxynitride (SiON). The first and second inorganic encapsulation layers 310 and 330 may be formed by using chemical vapor deposition.

The organic encapsulation layer 320 may further include polyethylene terephthalate, polyethylene naphthalate, polycarbonate, polyimide, polyethylene sulfonate, polyoxymethylene, polyarylate, hexamethyldisiloxane (HMDSO), acrylic resin, or a combination thereof.

The touch sensing unit 20 may be disposed on the display panel 10. The touch sensing unit 20 may have a multi-layer structure. The touch sensing unit 20 may include the driving electrode TE (see FIG. 4), a signal wiring connected to the driving electrode TE, the sensing electrode RE (see FIG. 4), a signal wiring connected to the sensing electrode RE, and at least one insulating layer.

The touch sensing unit 20 may include a first touch insulating layer 21, a first touch conductive layer MTL1, a second touch insulating layer 22, a second touch conductive layer MTL2, and a third touch insulating layer 23.

The first touch insulating layer 21 may be disposed directly on the encapsulation member 300. The first touch insulating layer 21 may include an inorganic material or an organic material, and may have a single or multi-layer structure.

The first touch insulating layer 21 may prevent damage to the encapsulation member 300 and may block a signal interference signal that may occur when driving the touch sensing unit 20.

Each of the first touch conductive layer MTL1 and the second touch conductive layer MTL2 may have a single-layer structure or a stacked multi-layer structure. The conductive layer having the single-layer structure may include a metal layer or a transparent conductive layer. The metal layer may include molybdenum (Mo), silver (Ag), titanium (Ti), copper (Cu), aluminum (Al), or an alloy thereof. The transparent conductive layer may include a transparent conductive oxide such as indium tin oxide (ITO), indium zinc oxide (IZO), zinc oxide (ZnO), or indium tin zinc oxide (ITZO). In addition, the transparent conductive layer may include a conductive polymer such as PEDOT, metal nanowires, or graphene.

The conductive layer having the multi-layer structure may include multiple metal layers. The multiple metal layers may have, for example, a three-layer structure of Ti/Al/Ti. The conductive layer having the multi-layer structure may include at least one metal layer and at least one transparent conductive layer.

In an embodiment, each of the first touch conductive layer MTL1 and the second touch conductive layer MTL2 includes a plurality of patterns. The first touch conductive layer MTL1 may include first conductive patterns, and the second touch conductive layer MTL2 may include second conductive patterns. The first conductive patterns and the second conductive patterns may form a touch sensor.

The first touch conductive layer MTL1 and the second touch conductive layer MTL2 may be electrically connected through a contact hole. In an embodiment, the first touch conductive layer MTL1 and the second touch conductive layer MTL2 may have a mesh structure through which light emitted from the organic light-emitting diode OLED may pass. In this case, the first touch conductive layer MTL1 and the second touch conductive layer MTL2 may be formed so as not to overlap the emission area EA.

The second touch insulating layer 22 may include an organic material. The organic material may include at least one material selected from the group consisting of an acrylic resin, a methacrylic resin, polyisoprene, a vinyl resin, an epoxy resin, a urethane resin, a cellulose resin, and a perylene resin. The second touch insulating layer 22 may further include an inorganic material. The inorganic material may include at least one material selected from the group consisting of silicon nitride (SiN_{X}), aluminum nitride (AlN), zirconium nitride (ZrN), titanium nitride (TiN), hafnium nitride (HfN), tantalum nitride (TaN), silicon oxide (SiOₓ), aluminum oxide (Al₂O₃), titanium oxide (TiO₂), tin oxide (SnO₂), cerium oxide (CeO₂), and silicon oxynitride (SiON).

The third touch insulating layer 23 may be disposed on the second touch conductive layer MTL2. The third touch insulating layer 23 may have a single or multi-layer structure. The third touch insulating layer 23 may include an organic material, an inorganic material, or a composite material thereof.

Some of the driving electrode TE, the sensing electrode RE, the first connection pattern SP1, and the second connection pattern SP2 described with reference to FIG. 4 may be disposed on the first touch insulating layer 21 and be included in the first conductive layer MTL1, and the rest may be disposed on the second touch insulating layer 22 and be included in the second conductive layer MTL2.

In an embodiment, the first touch conductive layer MTL1 may include the second connection patterns SP2, and the second touch conductive layer MTL2 may include the driving electrodes TE, the sensing electrodes RE, and the first connection patterns SP1. In an embodiment, the first touch conductive layer MTL1 may include the driving electrodes TE, the sensing electrodes RE, and the first connection patterns SP1, and the second touch conductive layer MTL2 may include the second connection patterns SP2. In an embodiment, the first touch conductive layer MTL1 may include the driving electrodes TE and the first connection patterns SP1, and the second touch conductive layer MTL2 may include the sensing electrodes RE and the second connection patterns SP2. In this case, the driving electrodes TE and the first connection patterns SP1 may be disposed on the same layer and may be integrally connected to each other. If the sensing electrodes RE and the second connection patterns SP2 are disposed on the same layer, a contact hole may not be formed in an insulating layer between the first touch conductive layer MTL1 and the second touch conductive layer MTL2.

Although the touch sensing unit 20 is formed directly on the display panel 10 without being provided as a separate panel in FIG. 19, the disclosure is not limited thereto. In an embodiment, the touch sensing unit 20 may be provided as a separate functional module and may be coupled to the display panel 10 by using an optically clear adhesive or the like.

In an embodiment, the optical functional layer 30 may be formed on the touch sensing unit 20.

A touch sensing unit according to an embodiment may increase the accuracy of touch sensing by forming the different areas which each of touch electrodes in touch sensors arranged in different columns or rows occupies.

A display apparatus according to an embodiment may increase the accuracy of touch sensing by including a touch sensing unit in which the areas of touch electrodes included in touch sensors located in different columns or rows are different from each other.

The above effects are only an example, and the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While the present disclosure has been described with reference to the drawings and embodiments thereof, it will be understood by one of ordinary skill in the art that various changes in form and details may be made thereto without departing from the spirit and scope of the present disclosure as set forth in the following claims.

1. A touch sensing unit comprising touch sensors arranged in first to n^{th} rows and first to m^{th} columns,
wherein each of the touch sensors comprises a touch electrode,
wherein a number of the touch sensors located in an a^{th} column is greater than a number of the touch sensors located in a b^{th} column (a and b are different natural numbers equal to or less than m), and
wherein an area of the touch electrode of a first touch sensor located in the a^{th} column is less than an area of the touch electrode of a second touch sensor located in the b^{th} column.

2. The touch sensing unit of claim 1, wherein the touch electrode comprises a driving electrode and a sensing electrode, and
wherein an area of the driving electrode of the first touch sensor is less than an area of the driving electrode of the second touch sensor.

3. The touch sensing unit of claim 2, wherein an area of the sensing electrode of the first touch sensor is less than an area of the sensing electrode of the second touch sensor.

4. The touch sensing unit of claim 2, wherein, in a plan view, an interval between the driving electrode and the sensing electrode of the first touch sensor is greater than an interval between the driving electrode and the sensing electrode of the second touch sensor.

5. The touch sensing unit of claim 2, wherein the first touch sensor further comprises a first dummy pattern located inside each of the driving electrode and the sensing electrode of the first touch sensor.

6. The touch sensing unit of claim 5, wherein the second touch sensor further comprises a second dummy pattern located inside each of the driving electrode and the sensing electrode of the second touch sensor, and
wherein an area of the first dummy pattern of the first touch sensor is greater than an area of the second dummy pattern of the second touch sensor.

7. The touch sensing unit of claim 5, wherein, in a plan view, an interval between the driving electrode and the sensing electrode of the first touch sensor is same as an interval between the driving electrode and the sensing electrode of the second touch sensor.

8. The touch sensing unit of claim 5, wherein, in a plan view, an interval between the driving electrode and the sensing electrode of the first touch sensor is less than an interval between the driving electrode and the sensing electrode of the second touch sensor.

9. The touch sensing unit of claim 5, wherein each of the driving electrode and the sensing electrode of the first touch sensor has a ring shape, and each of the driving electrode and the sensing electrode of the second touch sensor has a non-ring shape.

10. The touch sensing unit of claim 1, wherein a number of the touch sensors located in a c^{th} column is less than a number of the touch sensors located in the b^{th} column (c is a natural number different from a and b and equal to or less than m), and
wherein an area of the touch electrode of the second touch sensor located in the b^{th} column is less than an area of the touch electrode of a third touch sensor located in the c^{th} column.

11. The touch sensing unit of claim 1, wherein an area of the touch electrode of a fourth touch sensor located in the a^{th} column and located in a different row than the first touch sensor is same as an area of the touch electrode of the first touch sensor.

12. The touch sensing unit of claim 1, wherein the first touch sensor and the second touch sensor are located in a same row, and
wherein an area of the touch electrode of a fourth touch sensor located in the a^{th} column and located in a different row than the first touch sensor is different from an area of the touch electrode of the first touch sensor.

13. The touch sensing unit of claim 12, wherein a number of the touch sensors located in a p^{th} row is greater than a number of the touch sensors located in a q^{th} row (p and q are different natural numbers equal to or less than n),
wherein the first touch sensor is located in the p^{th} row, and the fourth touch sensor is located in the q^{th} row, and
wherein an area of the touch electrode of the first touch sensor is less than an area of the touch electrode of the fourth touch sensor.

14. A display apparatus comprising:
a substrate;
a display layer disposed on the substrate and comprising a light-emitting element; and
a touch sensing unit disposed on the display layer and comprising touch sensors arranged in first to n^{th} rows and first to m^{th} columns, each of the touch sensors comprising a touch electrode (each of n and m is a natural number each equal to or greater than 3),
wherein a number of the touch sensors located in an a^{th} column is greater than a number of the touch sensors located in a b^{th} column (a and b are different natural numbers equal to or less than m), and
wherein an area of the touch electrode of a first touch sensor located in the a^{th} column is less than an area of the touch electrode of a second touch sensor located in the b^{th} column.

15. The display apparatus of claim 14, wherein the touch electrode comprises a driving electrode and a sensing electrode, and
wherein an area of the driving electrode of the first touch sensor is less than an area of the driving electrode of the second touch sensor.

16. The display apparatus of claim 15, wherein, in a plan view, an interval between the driving electrode and the sensing electrode of the first touch sensor is greater than an interval between the driving electrode and the sensing electrode of the second touch sensor.

17. The display apparatus of claim 15, wherein the first touch sensor further comprises a first dummy pattern located inside each of the driving electrode and the sensing electrode of the first touch sensor.

18. The display apparatus of claim 17, wherein the second touch sensor further comprises a second dummy pattern located inside each of the driving electrode and the sensing electrode of the second touch sensor, and
wherein an area of the first dummy pattern of the first touch sensor is greater than an area of the second dummy pattern of the second touch sensor.

19. The display apparatus of claim 17, wherein, in a plan view, an interval between the driving electrode and the sensing electrode of the first touch sensor is less than an interval between the driving electrode and the sensing electrode of the second touch sensor.

20. (canceled)

21. An electronic device comprising:
a substrate;
a display layer disposed on the substrate and comprising a light-emitting element; and
a touch sensing unit disposed on the display layer and comprising touch sensors arranged in first to n^{th} rows and first to m^{th} columns, each of the touch sensors comprising a touch electrode (each of n and m is a natural number each equal to or greater than 3),
wherein a number of the touch sensors located in an a^{th} column is greater than a number of the touch sensors located in a b^{th} column (a and b are different natural numbers equal to or less than m), and
wherein an area of the touch electrode of a first touch sensor located in the a^{th} column is less than an area of the touch electrode of a second touch sensor located in the b^{th} column.
